(19) United States
(12) Patent Application Publication
(10) Pub. No.: US 2026/0219538 A1
(43) Pub. Date: Jul. 30, 2026

(54) ARRAY SUBSTRATE, DISPLAY PANEL AND DISPLAY APPARATUS

(71) Applicants: Chongqing BOE Optoelectronics Technology Co., Ltd., Chongqing (CN); BOE Technology Group Co., Ltd., Beijing (CN)

(72) Inventors: Zhongshan WU, Beijing (CN); Xiaoyuan WANG, Beijing (CN); Hui GUO, Beijing (CN); Yuanyuan PENG, Beijing (CN); Jiandong GUO, Beijing (CN); Kun YANG, Beijing (CN)

(21) Appl. No.: 19/148,434

(22) PCT Filed: Apr. 17, 2024
(86) PCT No.: PCT/CN2024/088343

§ 371 Date: Jul. 16, 2025

(30) Foreign Application Priority Data
May 26, 2023 (CN) 202310612095.1

(51) Int. Cl. G02F 1/1362; G02F 1/1343; G02F 1/1368

(52) U.S. Cl. CPC G02F 1/136286; G02F 1/134309; G02F 1/13685

(57) ABSTRACT

Disclosed in the present disclosure are an array substrate, a display panel and a display apparatus. The array substrate includes: a first base substrate, which includes a sub-pixel region and a wiring region; a thin film transistor, which includes: a first pole; a first electrode, which includes a plurality of first opening regions, wherein the orthographic projection of each first opening region on the first base substrate overlaps with the orthographic projection of the first electrode on the first base substrate; and a second electrode, which includes: a first connection portion, wherein the first connection portion includes a first connection sub-portion and a second connection sub-portion. The second connection sub-portion includes structures respectively located on two opposite sides of the first connection sub-portion.

### CROSS REFERENCE TO RELATED APPLICATION

This application is a national phase entry under 35 U.S.C § 371 of International Application No. PCT/CN2024/088343, filed on Apr. 17, 2024, which claims priority to Chinese Patent Application No. 202310612095.1, filed with the China National Intellectual Property Administration on May 26, 2023, and entitled “Array Substrate, Display Panel, and Display Device”, the entire contents of which are incorporated by reference in their entireties.

### TECHNICAL FIELD

The present disclosure relates to the field of display technology, and in particular to an array substrate, a display panel and a display device.

### BACKGROUND

With the continuous development and application of display technology, users have higher and higher requirements for the display effect of electronic display products.

Currently, liquid crystal display products adopt dual gate design in order to reduce cost. However, due to the existence of parasitic capacitance between the pixel electrode and the common electrode, when the pixel electrode corresponding to each sub-pixel is shifted as a whole due to process deviation, it will lead to a large difference in the parasitic capacitance of different pixel electrodes, and a large difference in the charging rate of different pixel electrodes, which will lead to a difference in the brightness of different sub-pixels. When a user moves to view, for example, shaking his or her head in the course of using the display product, the brightness of the brighter sub-pixels is superimposed on each other, and the brightness of the darker sub-pixels is also superimposed on each other, which aggravates the difference in brightness, and then a shaking of the head pattern occurs, which affects the display effect of the display product.

### SUMMARY

Embodiments of the present disclosure provide an array substrate, a display panel and a display device, which are used to avoid a shaking of the head pattern.

Embodiments of the present disclosure provide an array substrate, including:
a first base substrate, including a plurality of sub-pixel areas arrayed along a first direction and a second direction and a wiring area between adjacent the sub-pixel areas; where the first direction intersects with the second direction;
a plurality of thin-film transistors, disposed on one side of the first base substrate in the wiring area; where each of the plurality of thin-film transistors includes a first pole, a second pole and a third pole;
a first electrode, disposed on one side of the first pole back from the first base substrate, and including a plurality of first opening areas; where an orthographic projection of the first opening areas on the first base substrate falls within the wiring area, and the orthographic projection of the first opening areas on the first base substrate overlaps with an orthographic projection of the first pole on the first base substrate;
a plurality of second electrodes, disposed on the same side of the first base substrate as the first electrode; where each of the plurality of second electrodes includes a first connection portion; the first connection portion includes a first sub-connection portion electrically connected to the first pole and a second sub-connection portion electrically connected to the first sub-connection portion; the second sub-connection portion includes structures respectively located on opposite sides of the first connection portion; an orthographic projection of the first sub-connection portion on the first base substrate falls within the orthographic projection of the first opening areas on the first base substrate, and an orthographic projection of the second sub-connection portion on the first base substrate overlaps with the orthographic projection of the first pole on the first base substrate and the orthographic projection of the first opening areas on the first base substrate.

In some embodiments, the second sub-connection portion includes a first structure and a second structure;
in the first direction, the first structure and the second structure are disposed on both sides of the first sub-connection portion respectively.

In some embodiments, the first structure includes a first region adjacent to the first sub-connection portion, and the second structure includes a second region adjacent to the first sub-connection portion;
in the first direction, a spacing between the orthographic projection of the first sub-connection portion on the first base substrate and an orthographic projection of an edge of the first opening area on a side of the first sub-connection portion toward the first structure on the first base substrate is less than a width of an orthographic projection of the first region on the first base substrate, and a spacing between the orthographic projection of the first sub-connection portion on the first base substrate and an orthographic projection of an edge of the first opening area on a side of the first sub-connection portion toward the second structure on the first base substrate is less than a width of an orthographic projection of the second region on the first base substrate.

In some embodiments,
in the second direction, a maximum width of the orthographic projection of the first sub-connection portion on the first base substrate is less than a width of the orthographic projection of the first opening areas on the first base substrate, the maximum width of the orthographic projection of the first sub-connection portion on the first base substrate is greater than a total width of an orthographic projection of the second sub-connection portion in the first region on the first base substrate, the maximum width of the orthographic projection of the first sub-connection portion on the first base substrate is greater than a total width of an orthographic projection of the second sub-connection portion in the second region on the first base substrate.

In some embodiments, the first structure includes at least one first sub-structure connected to the first sub-connection portion; the second structure includes at least one second sub-structure connected to the first sub-connection portion;
in the second direction, the total width of the orthographic projection of the first sub-structure in the first region on the first base substrate is equal to the total width of the orthographic projection of the second sub-structure in the second region on the first base substrate.

In some embodiments, the plurality of sub-pixel areas and the plurality of wiring areas are divided into a plurality of sub-pixel columns arranged along the first direction and extending along the second direction; the plurality of second electrodes include a plurality of first sub-electrodes and a plurality of second sub-electrodes;
the first sub-electrodes and the thin-film transistors electrically connected to the first sub-electrodes are located in the same sub-pixel column;
the second sub-electrodes and the thin-film transistors electrically connected to the second sub-electrodes are located in different sub-pixel columns.

In some embodiments, the second electrode further includes: a pixel portion corresponding to the sub-pixel area and connected to the first connection portion;
the second sub-connection portion of the first sub-electrode further includes: a third structure; in the second direction, the third structure is between the first structure and the pixel portion; the third structure is electrically connected to the pixel portion, and at least one of the first sub-connection portion and the first structure is connected to the third structure.

In some embodiments, in the first sub-electrode, an orthographic projection of the third structure on the first base substrate does not overlap the orthographic projection of the first opening areas on the first base substrate.

In some embodiments, in the first sub-electrode and the thin-film transistor corresponding to the first sub-electrode, in the first direction, the first structure and the second pole are located on the same side of the first opening area; an orthographic projection of the first structure on the first base substrate overlaps with an orthographic projection of the second pole on the first base substrate.

In some embodiments, in the first sub-electrode, in the first direction, a length of the orthographic projection of the first structure on the first base substrate is greater than a length of an orthographic projection of the second structure on the first base substrate.

In some embodiments, an orthographic projection of the third structure on the first base substrate overlaps with the first opening area.

In some embodiments, in the first sub-electrode, the second sub-connection portion further includes a fourth structure; in the second direction, the third structure and the fourth structure are disposed on both sides of the first sub-connection portion respectively.

In some embodiments, in the first sub-electrode, the third structure includes a third region adjacent to the first sub-connection portion, and the fourth structure includes a fourth region adjacent to the first sub-connection portion;
in the second direction, a spacing between the orthographic projection of the first sub-connection portion on the first base substrate and an orthographic projection of an edge of the first opening area on a side of the first sub-connection portion toward the third structure on the first base substrate is less than a width of an orthographic projection of the third region on the first base substrate, and a spacing between the orthographic projection of the first sub-connection portion on the first base substrate and an orthographic projection of an edge of the first opening area on a side of the first sub-connection portion toward the fourth structure on the first base substrate is less than a width of an orthographic projection of the fourth region on the first base substrate.

In some embodiments, the third structure includes at least one third sub-structure connected to the first sub-connection portion, and the fourth structure includes at least one fourth sub-structure connected to the first sub-connection portion;
in the first direction, a total width of an orthographic projection of the third sub-structure in the third region on the first base substrate is equal to a total width of an orthographic projection of the fourth sub-structure in the fourth region on the first base substrate.

In some embodiments, the second sub-connection portion of the second sub-electrode further includes: a fifth structure, the fifth structure is connected to the first structure and the pixel portion in the second direction between the first structure and the pixel portion.

In some embodiments, an orthographic projection of the pixel portion of the first sub-electrode on the first base substrate has a first overlapping area with an orthographic projection of the first electrode on the first base substrate, an orthographic projection of the pixel portion of the second sub-electrode on the first base substrate has a second overlapping area with the orthographic projection of the first electrode on the first base substrate; an orthographic projection of the first connection portion of the first sub-electrode on the first base substrate has a third overlapping area with the orthographic projection of the first electrode on the first base substrate, an orthographic projection of the first connection portion of the second sub-electrode on the first base substrate has a fourth overlapping area with the orthographic projection of the first electrode on the first base substrate; the first overlapping area is approximately equal to the second overlapping area, and the third overlapping area is approximately equal to the fourth overlapping area.

In some embodiments, the first electrode further includes a plurality of second opening areas disposed in the wiring area; an orthographic projection of the second opening areas on the first base substrate overlaps with an orthographic projection of the first connection portion of the second sub-electrode on the first base substrate.

In some embodiments, the first sub-electrode is arranged alternately with the second sub-electrode in the first direction and the first sub-electrode is arranged alternately with the second sub-electrode in the second direction.

In some embodiments, the array substrate further includes:
a plurality of data lines, disposed on one side of the first electrode toward the first base substrate, and arranged in the first direction and extending in the second direction; where each of the plurality of data lines is electrically connected to the second pole of the thin-film transistor; and two sub-pixel columns are provided between two adjacent data lines;
the plurality of wiring areas, divided into a plurality of wiring area rows extending in the first direction; where the wiring area rows include a plurality of first sub-areas and a plurality of second sub-areas; each of the plurality of first sub-areas is adjacent to the sub-pixel areas in the second direction, and the first sub-area is located between two adjacent data lines; each of the plurality of second sub-areas is adjacent to the sub-pixel areas in the second direction, and the second sub-area is located between two adjacent data lines; the first sub-areas are arranged alternately with the second sub-areas in the second direction;
the plurality of thin-film transistors, including a plurality of first thin-film transistors and a plurality of second thin-film transistors; where the first thin-film transistor is electrically connected to the first sub-electrode, and the second thin-film transistor is electrically connected to the second sub-electrode; the first thin-film transistor is disposed in the first sub-area, and the second thin-film transistor is disposed in the second sub-area;
where in an M^{th} wiring area row, an m number of second sub-areas are provided between two first sub-areas; in an (M+1)^{th} wiring area row, an m number of first sub-areas are provided between two second sub-areas; where M is an integer greater than or equal to 1, m is an integer greater than 1, and (M+1) is less than or equal to a total number of the wiring area rows.

In some embodiments, m=2.

In some embodiments, the array substrate further includes:
a plurality of scan lines, located on one side of the first electrode toward the first base substrate in the wiring area; where the plurality of scan lines extend in the first direction and are arranged along the second direction; the plurality of scan lines include a plurality of first scan lines and a plurality of second scan lines; the first scan lines are arranged alternately with the second scan lines; and one first scan line and one second scan line are provided between two adjacent sub-pixel areas in the second direction; the scan lines are disposed in the same layer with and electrically connected to the third pole of the thin-film transistor; the scan lines include a first compensation portion corresponding to the thin-film transistor;
the first pole of the thin-film transistor, including a first portion, and a second portion and a third portion disposed in the first direction on both sides of the first portion respectively;
where an orthographic projection of the first portion on the first base substrate falls within an orthographic projection of an area between the third pole and the first compensation portion on the first base substrate, an orthographic projection of the second portion on the first base substrate overlaps with an orthographic projection of the third pole on the first base substrate, and an orthographic projection of the third portion on the first base substrate overlaps with an orthographic projection of the first compensation portion on the first base substrate.

In some embodiments, in the second direction, a width of the orthographic projection of the third portion on the first base substrate is equal to a width of an orthographic projection of one side of the second portion proximate to the first portion on the first base substrate.

In some embodiments, in the first sub-area, the scan line includes: a first portion extending in the first direction, and a second portion extending in a third direction and connected to the first portion; the third direction intersects with both the first direction and the second direction; and the first compensation portion is disposed on one side of the second portion toward the third pole.

In some embodiments, in the second sub-area, the scan line includes: a second portion extending in the first direction, and a third portion extending in a third direction and connected to the second portion; the third direction intersects with both the first direction and the second direction; the first compensation portion is disposed on one side of the third portion toward the third pole.

In some embodiments, in the second sub-area, the scan line includes: a second portion extending in the first direction; the first compensation portion is connected to the second portion in the second direction, and the first compensation portion and the third pole are located on the same side of the second portion in the second direction.

In some embodiments, in the second sub-area, an orthographic projection of the second opening area on the first base substrate does not overlap the scan lines, and the orthographic projection of the second opening area on the first base substrate falls within an orthographic projection of a region between two adjacent first compensation portions on the first base substrate.

In some embodiments, in at least a part of the second sub-area, the second opening areas corresponding to the first connection portions of two second sub-electrodes are integrally connected.

In some embodiments, the array substrate includes a plurality of scan lines;
an orthographic projection of the pixel portion on the first base substrate overlaps with an orthographic projection of the scan lines on the first base substrate.

In some embodiments, the first electrode includes a plurality of slit units, or the pixel portion includes a slit unit; an orthographic projection of the slit unit on the first base substrate overlaps with the sub-pixel area;
the slit unit includes a first sub-unit and a second sub-unit arranged alternately in the second direction; the first sub-unit includes a plurality of first slits extending in a fourth direction and arranged along the first direction, and the second sub-unit includes a plurality of second slits extending in a fifth direction and arranged along the first direction; the fourth direction intersects with the fifth direction, and the fourth direction intersects with both the first direction and the second direction; the fifth direction intersects with both the first direction and the second direction;
the array substrate further includes a plurality of first electrode wires located on one side of the first electrode towards the first base substrate and extending along the first direction and arranged along the second direction; the first electrode wires are electrically connected to the first electrode;
an orthographic projection of the first electrode wires on the first base substrate overlaps with an orthographic projection of a connection location of the first sub-unit and the second sub-unit on the first base substrate.

In some embodiments, the array substrate further includes:
peripheral electrode wires, wherein an orthographic projection of the peripheral electrode wires on the first base substrate surrounds the plurality of sub-pixel areas and the plurality of wiring areas;
the first electrode wire is electrically connected to the peripheral first electrode wire.

In some embodiments, the array substrate further includes:
a plurality of data lines;
a plurality of second electrode wires, disposed on the same layer as the first electrode wires and electrically connected to the first electrode wires in the wiring area, and extending in the second direction; where two columns of the sub-pixels are provided between two adjacent second electrode wires; and the second electrode wires are arranged alternately with the data lines in the first direction.

Embodiments of the present disclosure provide a display panel, including:
the array substrate according to the embodiments of the present disclosure;
an opposite substrate, disposed opposite the array substrate;
a liquid crystal layer, between the array substrate and the opposite substrate.

In some embodiments, the array substrate includes a plurality of data lines;
the opposite substrate includes:

a second base substrate, and
a plurality of spacers disposed on one side of the second base substrate toward a liquid crystal layer; an orthographic projection of the spacers on the first base substrate falls within the wiring area, and the orthographic projection of the spacers on the first base substrate overlaps with an orthographic projection of the data lines on the first base substrate.

Embodiments of the present disclosure provide a display device, including the display panel according to the embodiments of the present disclosure.

### BRIEF DESCRIPTION OF FIGURES

In order to more clearly illustrate the technical solutions in the embodiments of the present disclosure, the accompanying drawings that need to be used in the description of the embodiments will be briefly introduced below, and it will be obvious that the accompanying drawings in the following description are only some of the embodiments of the present disclosure, and for the person of ordinary skill in the field, other accompanying drawings can be obtained based on these drawings without putting in creative labor.

FIG. 1 shows a schematic diagram of a structure of an array substrate provided by the related art.

FIG. 2 shows a schematic diagram of a structure of an array substrate provided by embodiments of the present disclosure.

FIG. 3 shows a schematic diagram of a structure along AA′ in FIG. 2 provided by embodiments of the present disclosure.

FIG. 4 shows a schematic diagram of the structure of another type of array substrate provided by embodiments of the present disclosure.

FIG. 5 shows a schematic diagram of the structure of yet another type of array substrate provided by embodiments of the present disclosure.

FIG. 6 shows a schematic diagram of the structure of yet another type of array substrate provided by embodiments of the present disclosure.

FIG. 7 shows a schematic diagram of the structure of yet another type of array substrate provided by embodiments of the present disclosure.

FIG. 8 shows a schematic diagram of the structure of yet another type of array substrate provided by embodiments of the present disclosure.

FIG. 9 shows a schematic diagram of the structure of yet another type of array substrate provided by embodiments of the present disclosure.

FIG. 10 shows a schematic diagram of the structure of yet another type of array substrate provided by embodiments of the present disclosure.

FIG. 11 shows a schematic diagram of the structure of yet another type of array substrate provided by embodiments of the present disclosure.

FIG. 12 shows a schematic diagram of the structure of yet another type of array substrate provided by embodiments of the present disclosure.

FIG. 13 shows a schematic diagram of the structure of yet another type of array substrate provided by embodiments of the present disclosure.

FIG. 14 shows a schematic diagram of the structure of yet another type of array substrate provided by embodiments of the present disclosure.

FIG. 15 shows a schematic diagram of the structure of yet another type of array substrate provided by embodiments of the present disclosure.

FIG. 16 shows a schematic diagram of the structure of a first electrode wire and a second electrode wire provided by embodiments of the present disclosure.

FIG. 17 shows a schematic diagram of the structure of a display panel provided by embodiments of the present disclosure.

FIG. 18 shows a schematic diagram of the structure of another display panel provided by embodiments of the present disclosure.

### DETAILED DESCRIPTION

In order to make the objects, technical solutions and advantages of the embodiments of the present disclosure clearer, the technical solutions of the embodiments of the present disclosure will be described clearly and completely in the following in conjunction with the accompanying drawings of the embodiments of the present disclosure. Obviously, the described embodiments are a part of the embodiments of the present disclosure, and not all of the embodiments. And the embodiments and the features in the embodiments of the present disclosure can be combined with each other without conflict. Based on the described embodiments of the present disclosure, all other embodiments obtained by a person of ordinary skill in the art without the need for creative labor are within the scope of protection of the present disclosure.

Unless otherwise defined, technical or scientific terms used in the present disclosure shall have the ordinary meaning understood by a person of ordinary skill in the field to which the present disclosure belongs. The terms “first”, “second”, and the like as used in the present disclosure do not indicate any order, number, or significance, but are only used to distinguish different components. The words “including” or “comprising” and the like are intended to indicate that the component or object preceded by the word encompasses the component or object listed after the word and their equivalents, and does not exclude other components or objects. Words such as “connected” or “coupled” are not limited to physical or mechanical connections, but can include electrical connections, whether direct or indirect.

It should be noted that the dimensions and shapes of the figures in the accompanying drawings do not reflect true proportions, but are intended to be illustrative of the present disclosure. And throughout the same or similar labeling denotes the same or similar elements or elements having the same or similar functions.

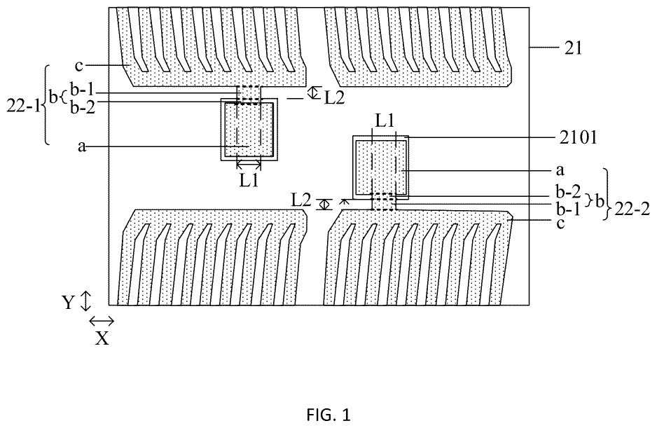

In the related art, as shown in FIG. 1, the array substrate includes a common electrode 21 and a plurality of pixel electrodes 22. The common electrode 21 has an opening area 2101. The pixel electrode 22 is divided into three portions a, b, and c. An orthographic projection of the portion a on a base substrate (not shown) falls into the opening area 2101, an orthographic projection of the portion c on the base substrate does not overlap with the opening area 2101, the portion b connects the portion a and the portion c, an orthographic projection of a region b-1 of the portion b on the base substrate does not overlap with the opening area 2101, and an orthographic projection of a region b-2 of the portion b on the base substrate overlaps with the opening area 2101. That is, in the pixel electrode 22, the orthographic projection of the portion c on the base substrate and the orthographic projection of the region b-1 on the base substrate overlap with an orthographic projection of the common electrode 21 on the base substrate. Typically, the orthographic projection of the portion c corresponding to each sub-pixel on the base substrate has a same overlapping area with the orthographic projection of the common electrode on the base substrate, where the same overlapping area is S1, and even if there is a deviation in the process, it does not affect the overlapping area with the common electrode. A width of the portion b of each pixel electrode 22 in a first direction X is L1, and ideally, a width of the region b-1 in a second direction Y is L2, and an overlapping area S2 between the orthographic projection of the portion b of each pixel electrode 22 on the base substrate and the orthographic projection of the common electrode 21 on the base substrate is L1×L2, and an overlapping area S3 between the orthographic projection of the pixel electrode 22 on the base substrate and the orthographic projection of the common electrode 21 on the base substrate is S3=S1+S2. However, in the second direction Y, if the plurality of pixel electrodes 22 are shifted upward or downward as a whole, for example, the pixel electrodes 22 are shifted upward by ΔL as a whole, the width of the region b-1 of the pixel electrode 22-1 in FIG. 1 in the second direction Y is L2-ΔL, and the overlapping area S2′ of the orthographic projection of the portion b of the pixel electrode 22-1 on the base substrate and the orthographic projection of the common electrode 21 on the base substrate is S2′=L1×(L2−ΔL)<S2, and the overlapping area S3′ of the orthographic projection of the pixel electrode 22-1 on the base substrate and the orthographic projection of the common electrode 21 on the base substrate is S3′<S3; in FIG. 1, the width of the region b-1 of the pixel electrode 22-2 in the second direction Y is L2+ΔL, the overlapping area S2′ of the orthographic projection of the portion b of the pixel electrode 22-2 on the base substrate and the orthographic projection of the common electrode 21 on the base substrate is S2′=L1×(L2+ΔL)>S2, and accordingly the overlapping area S3′ of the orthographic projection of the pixel electrode 22-2 on the base substrate and the orthographic projection of the common electrode 21 on the base substrate S3′>S3. That is, in the second direction Y, if the plurality of pixel electrodes 22 are shifted upward or downward as a whole, the width of the region b-1 in some pixel electrodes in the second direction Y is greater than L2, the width of the region b-1 in some pixel electrodes in the second direction Y is less than L2, and accordingly, the overlapping area of the orthographic projection of the portion b of a part of the pixel electrodes on the base substrate and the orthographic projection of the common electrode on the base substrate is larger than S2, and the overlapping area of the orthographic projection of the portion b of a part of the pixel electrodes on the base substrate and the orthographic projection of the common electrode 21 on the base substrate is smaller than S2. Consequently, the overlapping area of the orthographic projection of some of the pixel electrodes on the base substrate and the orthographic projection of the common electrode on the base substrate is greater than S3, the overlapping area of the orthographic projection of some of the pixel electrodes on the base substrate and the orthographic projection of the common electrode on the base substrate is smaller than S3, and the parasitic capacitance between different pixel electrodes and common electrodes is different, leading to a large difference in the charging rate of different pixel electrodes, which leads to a difference in the brightness of different sub-pixels, and is prone to appearing a shaking of the head pattern and affecting user experience.

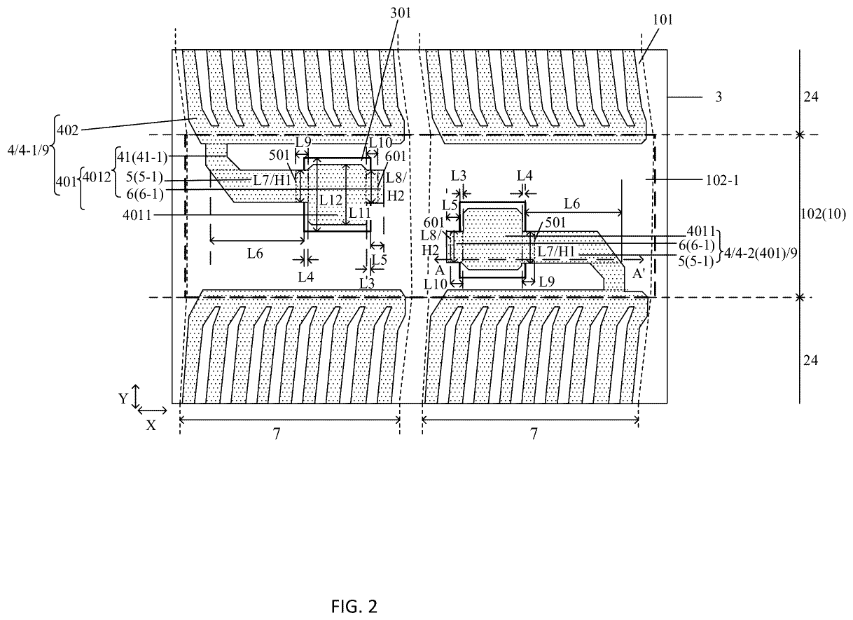

Embodiments of the present disclosure provide an array substrate, as shown in FIGS. 2 to 3, the array substrate including:
a first base substrate 1, including a plurality of sub-pixel areas 101 arrayed along a first direction X and a second direction Y, and a wiring area 102 between adjacent sub-pixel areas 101; where the first direction X intersects with the second direction Y;
a plurality of thin-film transistors 2, disposed on one side of the first base substrate 1 in the wiring area; where each thin-film transistor 2 of the plurality of thin-film transistors 2 includes a first pole D, a second pole S, and a third pole G;
a first electrode 3, disposed on one side of the first pole D back away from the first base substrate 1 and including a plurality of first opening areas 301; where an orthographic projection of the first opening areas 301 on the first base substrate 1 falls within the wiring area 102, and the orthographic projection of the first opening areas 301 on the first base substrate 1 overlaps with an orthographic projection of the first pole D on the first base substrate 1;
a plurality of second electrodes 4, disposed on the same side of the first base substrate 1 as the first electrode 3; where each second electrode 4 of the plurality of second electrodes 4 includes a first connection portion 401; the first connection portion 401 includes a first sub-connection portion 4011 electrically connected to the first pole D and a second sub-connection portion 4012 electrically connected to the first sub-connection portion 4011; the second sub-connection portion 4012 includes portions respectively disposed on opposite sides of the first sub-connection portion 4011; an orthographic projection of the first sub-connection portion 4011 on the first base substrate 1 falls within the orthographic projection of the first opening areas 301 on the first base substrate 1, and an orthographic projection of the second sub-connection portion 4012 on the first base substrate 1 overlaps with the orthographic projection of the first electrode 3 on the first base substrate 1.

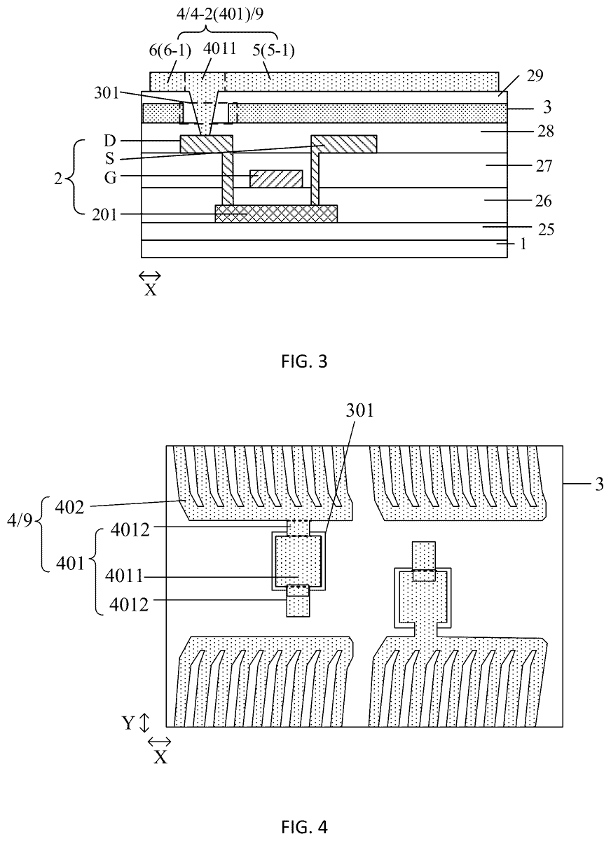

It is noted that the second sub-connection portion includes portions disposed on opposite two sides of the first sub-connection portion, for example, as shown in FIG. 2, the second sub-connection portion 4012 includes portions disposed on two sides of the first sub-connection portion 4011 in the first direction X; alternatively, as shown in FIG. 4, the second sub-connection portion 4012 includes portions disposed on two sides of the first sub-connection portion 4011 in the second direction Y; and, of course, the second sub-connection portion includes portions disposed on two sides of the first sub-connection portion in the first direction X, and portions disposed on two sides of the first sub-connection portion in the second direction Y.

In the array substrate provided in the embodiments of the present disclosure, the second electrode includes the first sub-connection portion and portions of the second sub-connection portion disposed on opposite sides of the first sub-connection portion, the orthographic projection of the first sub-connection portion on the base substrate falls into the orthographic projection of the first opening area of the first electrode on the base substrate, and the orthographic projection of the portions of the second sub-connection portion disposed on opposite sides of the first sub-connection portion on the base substrate overlaps with the orthographic projection of the first electrode on the base substrate and the orthographic projection of the first opening area on the base substrate. When there is an offset of all the second electrodes included in the array substrate due to a process deviation, i.e., the second sub-connection portions located on opposite two sides of the first sub-connection portion are offset, compared to the case in which there is no offset, opposite two sides of the first sub-connection portion are connected to the second sub-electrode. In each second electrode, an overlapping area of the orthographic projection of the portion of the second sub-connection portion located on one side of the first sub-connection portion on the base substrate and the orthographic projection of the first electrode on the base substrate increases, and an overlapping area of the orthographic projection of the portion of the second sub-connection portion located on the other side of the first sub-connection portion on the base substrate and the orthographic projection of the first electrode on the base substrate decreases. Since the second sub-connection portion disposed on the opposite two sides of the first sub-connection portion has the same offset, the change of the overlapping area of the orthographic projection of the second sub-connection portions disposed on the opposite two sides of the first sub-connection portion and the orthographic projection of the first electrode on the base substrate can complement. Even if the position of the second electrode is offset due to process deviations, the parasitic capacitance between each second electrode and the first electrode is still equal, avoiding significant differences in the charging rate of different second electrodes caused by different parasitic capacitances between the second electrode and the first electrode. When the array substrate is applied to a display product, differences in the brightness of different sub-pixel areas can thus be avoided. When the user moves to view, it can avoid aggravation of the brightness difference, avoid the appearance of a head-shaking pattern, improve the display effect, and enhance the user experience.

It should be noted that only a portion of the array substrate is shown in FIG. 2, and in order to visualize the positional relationship between the first electrode and the second electrode in the orthographic projection of the base substrate, the first base substrate and the thin-film transistor are not shown in FIG. 2; the first direction X is perpendicular to the second direction Y in FIG. 2, for example, for the purpose of providing an illustration. FIG. 3 shows a cross-sectional view along AA′ in FIG. 2.

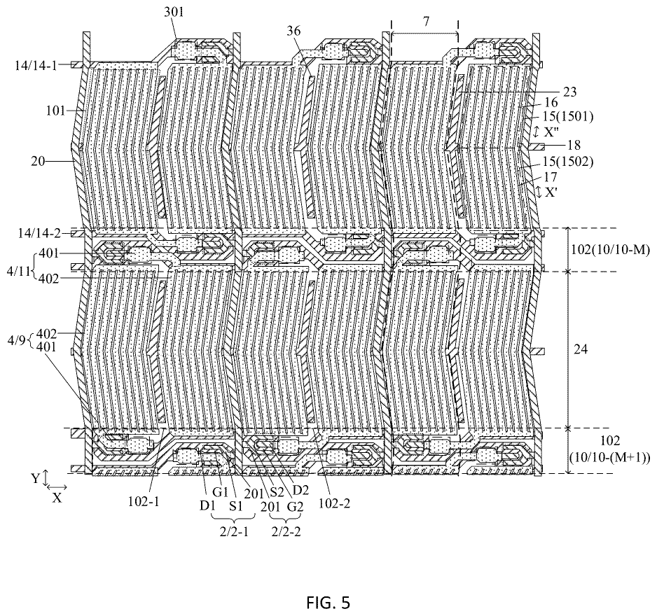

In some embodiments, as shown in FIGS. 2 and 5, the division of the plurality of sub-pixel areas 101 and the plurality of wiring areas 102 in the array substrate includes: a plurality of sub-pixel columns 7 arranged along the first direction X and extending along the second direction Y, a plurality of sub-pixel rows 24 extending along the first direction X and arranged along the second direction Y, and a plurality of wiring area rows 10 extending along the first direction X and arranged along the second direction Y; in the second direction Y, the sub-pixel rows 24 are arranged alternately with the wiring area rows 10.

As shown in FIG. 5, the array substrate further includes:
a plurality of scan lines 14, located on one side of the first electrode 3 toward the first base substrate 1 in the wiring area 102; where the plurality of scan lines 14 extends along the first direction X and are arranged along the second direction Y; the plurality of scan lines 14 includes a plurality of first scan lines 14-1 and a plurality of second scan lines 14-2; the first scan lines 14-1 are arranged alternately with the second scan lines 14-2; one first scan line 14-1 and one second scan line 14-2 are provided between two adjacent sub-pixel areas 101 in the second direction Y; the scan lines 14 are disposed in the same layer with and electrically connected to the third pole G of the thin-film transistor 2.

In a specific implementation, the scan line is disposed in a wiring area row, and one sub-pixel area row between two wiring area rows corresponds to one first scan line and one second scan line; that is, the one first scan line and the one second scan line are disposed on both sides of the one sub-pixel area row, respectively, in the second direction.

That is, the scan lines of the array substrate provided by the embodiments of the present disclosure are of a Dual Gate design.

In some embodiments, as shown in FIG. 5, the array substrate further includes:
a plurality of data lines 20, disposed on one side of the first electrode 3 toward the first base substrate 1 in the wiring area 102, arranged in the first direction X and extending in the second direction Y; where each data line 20 of the plurality of data lines 20 is electrically connected to the second pole S of the thin-film transistor 2; and two sub-pixel columns 7 are provided between two adjacent data lines 20;
a plurality of first electrode wires 18, disposed on one side of the first electrode 3 toward the first base substrate 1, extending along the first direction X, and arranged along the second direction Y;
a plurality of second electrode wires 23, disposed on the same layer as and electrically connected to the first electrode wires 18 in the wiring area 102, and extending along the second direction Y; where two sub-pixel columns 7 are provided between two adjacent second electrode wires 23; and the second electrode wires 23 are arranged alternately with the data lines 20 in the first direction X.

In some embodiments, as shown in FIG. 5, in the wiring area 102 between two adjacent sub-pixel area rows 24, the data lines 20 between two adjacent sub-pixel area columns 7 are electrically connected to two thin-film transistors 2, respectively, and the two thin-film transistors 2 are located on both sides of the data lines 24 in the first direction X, respectively.

The array substrate provided by the embodiments of the present disclosure can reduce the number of data lines and can reduce the cost because the scan lines are of a Dual Gate design, so that one data line can drive multiple sub-pixel area columns.

In some embodiments, as shown in FIG. 3, the second electrode 4 is located on one side of the first electrode 3 back away from the first base substrate 1. The first electrode 3 is, for example, a face electrode, and the plurality of first opening areas 301 are provided to avoid the place where the second electrode 4 is connected to the first pole D of the thin-film transistor 2.

In specific implementation, the third electrode is provided on the same layer as the scan line, and the electrically connected third electrode and the scan line may be integrally connected; the first electrode, the second electrode, and the data line are provided on the same layer, and the electrically connected second electrode and the data line may be integrally connected.

It should be noted that, in the present disclosure, the “same layer” refers to a layer structure formed by using the same film-forming process to form a film layer for producing a specific graphic, and then utilizing the same mask plate to form the layer structure through a single mask patterning process. That is, one mask (also called a photo-mask) corresponds to the single mask patterning process. Depending on the specific pattern, the single mask patterning process may include multiple exposure, development or etching processes, and the specific pattern in the formed layer structure may be continuous or discontinuous, and these specific patterns may be at the same height or have the same thickness, or may be at different heights or have different thicknesses.

In particular embodiments, for example, a first pole of the thin-film transistor is a drain electrode, a second pole of the thin-film transistor is a source electrode, and a third pole of the thin-film transistor is a gate electrode. The first electrode is a common electrode, the common electrode being provided, for example, as a whole layer; and the second electrode is a pixel electrode. That is, the array substrate provided in the embodiment of the present disclosure has the common electrode between the thin-film transistor and the pixel electrode. In the array substrate provided in the embodiments of the present disclosure, the first electrode, i.e., the common electrode is provided on the whole surface, and only the first opening area is hollowed out, so that the first electrode provided on the whole surface can effectively shield the signals of the scan line and the data line, and also shield the signals of the thin-film transistor, so that the second electrode is not subjected to interference from the following signal line, and does not generate parasitic capacitance between the film layer where the scan line is located and the second electrode, and thus does not affect the display quality.

It should be noted that the plurality of sub-pixel areas correspond to the regions divided by the plurality of scan lines, the plurality of data lines, and the plurality of second electrode wires, and when the array substrate is applied to the display product, the sub-pixel areas correspond to the sub-pixel opening areas of the display product, i.e., the orthographic projection of the sub-pixel areas on the first base substrate coincide with the orthographic projection of the sub-pixel opening areas of the display product on the first base substrate. The wiring area corresponds to the sub-pixel non-opening area of the display product.

In some embodiments, as shown in FIGS. 2 and 5, the plurality of second electrodes 4 include a plurality of first sub-electrodes 9 and a plurality of second sub-electrodes 11.

The plurality of thin-film transistors 2 include a plurality of first thin-film transistors 2-1 and a plurality of second thin-film transistors 2-2. The first thin-film transistors 2-1 are electrically connected to the first sub-electrode 9. The second thin-film transistors 2-2 are electrically connected to the second sub-electrode 11.

The first sub-electrode 9 and the thin-film transistor 2 electrically connected thereto, i.e. the first thin-film transistor 2-1, are located in the same sub-pixel column 7.

The second sub-electrode 11 and the thin-film transistor 2 electrically connected thereto, i.e. the second thin-film transistor 2-2, are located in a different sub-pixel column 7.

In some embodiments, as shown in FIGS. 2 and 5, the first sub-electrode 9 is arranged alternately with the second sub-electrode 11 in the first direction X, and the first sub-electrode 9 is arranged alternately with the second sub-electrode 11 in the second direction Y.

In some embodiments, as shown in FIG. 5, the plurality of wiring areas 102 are divided into: a plurality of wiring area rows 10 extending along the first direction X; the wiring area rows 10 include a plurality of first sub-areas 102-1 and a plurality of second sub-areas 102-2; each first sub-area 102-1 of the plurality of first sub-areas 102-1 is adjacent to the sub-pixel area 101 in the second direction Y, and the first sub-area 102-1 is between two adjacent data lines 20, and each second sub-area 102-2 of the plurality of second sub-areas 102-2 is adjacent to the sub-pixel area 101 in the second direction Y, and the second sub-area 102-2 is between two adjacent data lines 20; the first sub-area 102-1 is arranged alternately with the second sub-area 102-2 in the second direction Y.

The first thin-film transistor 2-1 is disposed in the first sub-area 102-1 and the second thin-film transistor 2-2 is disposed in the second sub-area 102-2.

In an M^{th} wiring area row 10-M, an m number of second sub-areas 102-2 are provided between two first sub-areas 102-1; in an (M+1)^{th} wiring area row, an m number of first sub-areas 102-1 are provided between two second sub-areas 102-2; where M is an integer greater than or equal to 1, m is an integer greater than 1, and (M+1) is less than or equal to a total number of the wiring area rows.

In some embodiments, as shown in FIG. 5, m=2.

That is, in the M^{th} wiring area row 10-M, one first sub-area 102-1 and two second sub-areas 102-2 serve as a repeating unit of the M^{th} row, and in the (M+1)^{th} wiring area row 10-(M+1), two first sub-areas 102-1 and one second sub-area 102-2 serve as a repeating unit of the M^{th} row.

In specific embodiments, the arrangement of the plurality of second electrodes 4 shown in FIG. 5 and the connection to the thin-film transistor 2 may serve as a repeating unit.

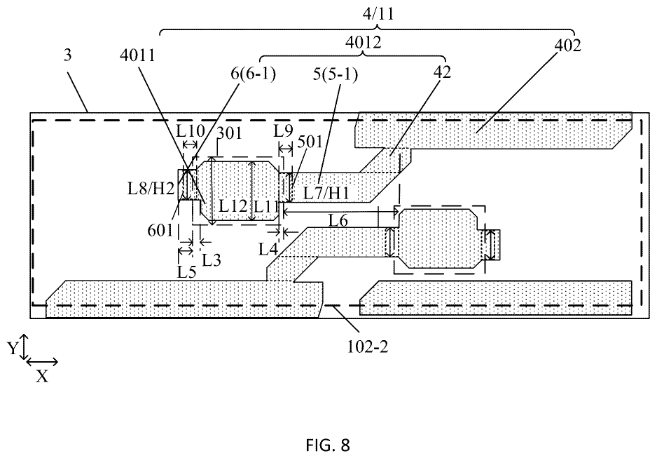

In some embodiments, as shown in FIGS. 2 and 8, the second sub-connection portion 4012 includes a first structure 5 and a second structure 6.

In the first direction X, the first structure 5 and the second structure 6 are disposed on both sides of the first sub-connection portion 4011, respectively.

It should be noted that the first connection portion 401 illustrated in FIG. 2 is the first connection portion 401 included in the first sub-electrode 9, and the first connection portion 401 illustrated in FIG. 8 is the first connection portion 401 included in the second sub-electrode 11.

In some embodiments, as shown in FIGS. 2 and 8, the second electrode 4 further includes: a pixel portion 402 corresponding to the sub-pixel area 101 and connected to the first connection portion 401.

As shown in FIG. 2, the second sub-connection portion 4012 of the first sub-electrode 9 further includes: a third structure 41; in the second direction Y, the third structure 41 is located between the first structure 5 and the pixel portion 402; the third structure 41 is electrically connected to the pixel portion 402, and at least one of the first sub-connection portion 4011 and the first structure 5 is coupled to the third structure 41.

As shown in FIG. 8, the second sub-connection portion 4012 of the second sub-electrode 11 further includes: a fifth structure 42; the fifth structure 42 is connected to the first structure 5 and between the first structure 5 and the pixel portion 402 in the second direction Y.

It should be noted that at least one of the first sub-connection portion and the first structure being connected to the third structure means: only the first sub-connection portion is connected to the third structure; or only the first structure is connected to the third structure; or, both the first sub-connection portion and the first structure are connected to the third structure.

It should be noted that the orthographic projection of the pixel portion on the base substrate and the orthographic projection of the first opening area on the base substrate do not overlap with each other, so that a positional shift of the pixel portion due to a process error does not affect the overlapping area of the pixel portion and the first electrode. In specific implementations, for example, the orthographic projection of the pixel portion on the base substrate and the orthographic projection of the first electrode on the base substrate are equal in overlapping areas in each of the second electrodes.

In the array substrate provided in the embodiments of the present disclosure, the first structure and the second structure disposed on both sides of the first sub-connection portion in the first direction X. When there is a situation in which all the second electrodes included in the array substrate are offset in the first direction X due to a process deviation, i.e., the first structure and the second structure disposed on opposite two sides of the first sub-connection portion are offset in the first direction X, compared to a situation where there is no offset in the first direction X, in each first connection portion, the overlapping area of the orthographic projection of one of the first structure and the second structure on the base substrate and the orthographic projection of the first electrode on the first base substrate increases, and the overlapping area of the orthographic projection of the other of the first structure and the second structure on the first base substrate and the orthographic projection of the first electrode on the first base substrate decreases, and since the first structure and the second structure have the same offset amount, the changes in the overlapping area of the orthographic projections of the first structure and the second structure and the first electrode on the first base substrate can be complementary. Even if the position of the second electrode is offset due to process deviations, the parasitic capacitance between each second electrode and the first electrode is still equal, avoiding significant differences in the charging rate of different second electrodes caused by different parasitic capacitances between the second electrode and the first electrode. When the array substrate is applied to a display product, differences in the brightness of different sub-pixel areas can thus be avoided. When the user moves to view, it can avoid aggravation of the brightness difference, avoid the appearance of a head-shaking pattern, improve the display effect, and enhance the user experience.

In some embodiments, as shown in FIGS. 2 and 8, the first structure 5 includes a first region 501 adjacent to the first sub-connection portion 4011, and the second structure 6 includes a second region 601 adjacent to the first sub-connection portion 4011.

In the first direction X, a spacing L4 between the orthographic projection of the first sub-connection portion 4011 on the first base substrate (not shown) and an orthographic projection of an edge of the first opening area 301 on a side of the first sub-connection portion 4011 toward the first structure on the first base substrate is less than a width L9 of an orthographic projection of the first region 501 on the first base substrate, and a spacing L3 between the orthographic projection of the first sub-connection portion 4011 on the first base substrate and an orthographic projection of an edge of the first opening area 301 on a side of the first sub-connection portion 4011 toward the second structure on the first base substrate is less than a width L10 of an orthographic projection of the second region 601 on the first base substrate.

In some embodiments, as shown in FIGS. 2 and 8, the first structure 5 includes at least one first sub-structure 5-1, and the second structure 6 includes at least one second sub-structure 6-1.

In the second direction Y, the total width H1 of the orthographic projection of the first sub-structure 5-1 of the first region 501 on the first base substrate is equal to the total width H2 of the orthographic projection of the second sub-structure 6-1 of the second region 601 on the first base substrate.

It should be noted that, ideally, i.e., when the first connection portion is not offset in the first direction X, the overlapping area of the orthographic projection of the first sub-structure included in the first structure on the first base substrate and the orthographic projection of the first electrode on the first base substrate is S4, and the overlapping area of the orthographic projection of the second sub-structure included in the second structure on the first base substrate and the orthographic projection of the first electrode on the first base substrate is S5. Taking each second electrode included in the array substrate as an example of offsetting ΔL to the left, and using FIG. 2 as an example for illustration, in FIG. 2, in the second electrode 4 labeled as 4-1 in the accompanying drawings, the overlapping area of the orthographic projection of the first sub-structure 5-1 included in the first structure 5 on the first base substrate and the orthographic projection of the first electrode 3 on the first base substrate is S4′=S4+H1×ΔL, and the overlapping area of the orthographic projection of the second sub-structure 6 included in the second structure 6 on the first base substrate and the orthographic projection of the first electrode 3 on the first base substrate is S5′=S5-H2×ΔL, S4′+S5′=S4+H1×ΔL+S5-H2×ΔL, and since H1=H2, therefore S4′+S5′=S4+S5; in the second electrode 4 labeled as 4-2 in the accompanying drawings, the overlapping area of the orthographic projection of the first sub-structure 5-1 included in the first structure 5 on the first base substrate and the orthographic projection of the first electrode 3 on the first base substrate is S4″=S4-H1×ΔL, and the overlapping area of the orthographic projection of the second sub-structure 6-1 included in the second structure 6 on the first base substrate and the orthographic projection of the first electrode 3 on the first base substrate is S5″=S5+H2×ΔL, S4″+S5″=S4-H1×ΔL+S5+H2×ΔL, and since H1=H2, S4″+S5″=S4+S5. It can be seen that, even if the position of the second electrode is offset due to process deviations, the overlapping areas of the orthographic projections of the first connection portion of different second electrodes and the first electrode on the base substrate are still equal, and the parasitic capacitance between each second electrode and the first electrode is still equal, avoiding significant differences in the charging rate of different second electrodes caused by different parasitic capacitances between the second electrode and the first electrode. When the array substrate is applied to a display product, differences in the brightness of different sub-pixel areas can thus be avoided. When the user moves to view, it can avoid aggravation of the brightness difference, avoid the appearance of a head-shaking pattern, improve the display effect, and enhance the user experience.

It should be noted that, ideally, i.e., when the first connection portion is not offset in the first direction X, L9-L4 is not less than an offset error in the first direction X, i.e., a relative offset between the first electrode and the second electrode caused by process deviations, and L10-L3 is not less than an offset error in the first direction X. Ideally, in each second electrode, L4=L3, and L4 is equal and L3 is equal in different second electrodes, i.e., different first sub-electrodes as well as different second sub-electrodes. If the second electrode is offset in the first direction, L4 is not equal to L3 in each second electrode, L4 is greater than L3 in some of the second electrodes, L4 is less than L3 in the remaining portion of the second electrodes, L4 is not exactly equal in the different second electrodes, and L3 is not exactly equal in the different second electrodes. Ideally, L4=L3 is in the range of greater than or equal to 1.0 micron and less than or equal to 5 microns, and the offset error between the first electrode and the second electrode is, for example, greater than or equal to 1.5 microns and less than or equal to 4 microns. L9-L4, L10-L3 are, for example, greater than or equal to 2.5 microns and less than or equal to 10 microns.

In some embodiments, as shown in FIGS. 2 and 8, in the second direction Y, the maximum width L11 of the orthographic projection of the first sub-connection portion 4011 on the first base substrate is less than the width L12 of the orthographic projection of the first opening area 301 on the first base substrate, the maximum width L11 of the orthographic projection of the first sub-connection portion 4011 on the first base substrate is greater than the total width H1 of the orthographic projection of the first sub-structure 5-1 of the first region 501 on the first base substrate, and the maximum width L11 of the orthographic projection of the first sub-connection portion 4011 on the first base substrate is greater than the total width H2 of the orthographic projection of the second sub-structure 6-1 of the second region 601 on the first base substrate.

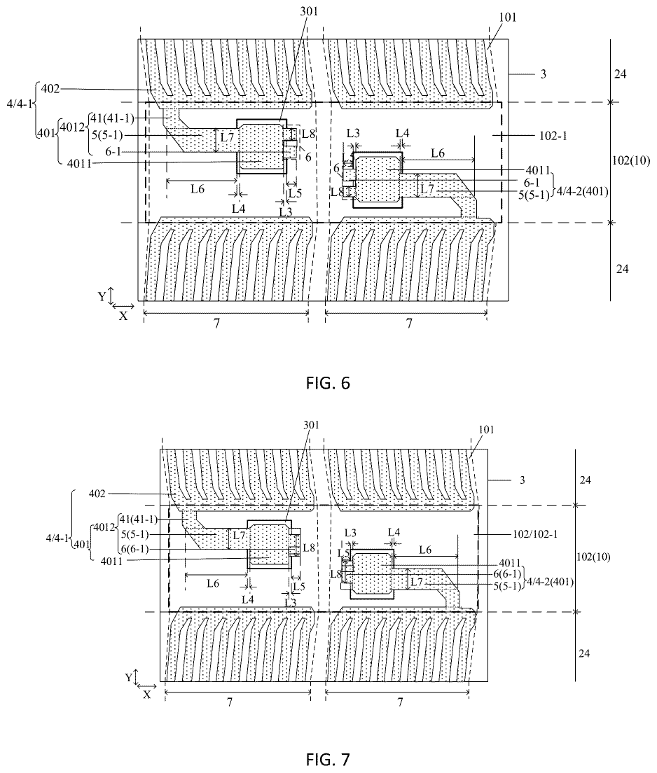

It should be noted that, in FIG. 2 and FIG. 8, for example, the first structure 5 includes one first sub-structure 5-1, and the second structure 6 includes one second sub-structure 6-1. In specific implementations, as shown in FIG. 6, the second structure 6 includes a plurality of second sub-structures 6-1. The second structure 6 in FIG. 6 includes 2 second sub-structures 6-1 arranged along the second direction Y. Of course, in specific implementations, the first structure may also include a plurality of first sub-structures. FIG. 6 is illustrated by way of example with the first sub-electrode 9. Of course, when the first structure in the second sub-electrode includes a plurality of first sub-structures, the plurality of first sub-structures are arranged in the second direction, and when the second structure includes a plurality of second sub-structures, the plurality of second sub-structures are arranged in the second direction, which will not be repeated herein.

In specific implementations, in the first direction X when the first structure includes the plurality of first sub-structures, the widths of the orthographic projections of the plurality of first sub-structures in the second direction Y on the first base substrate may be equal, and when the second structure includes the plurality of second sub-structures, the widths of the orthographic projections of the plurality of first sub-structures in the second direction Y on the first base substrate may be equal. Of course, the widths of the orthographic projections of the plurality of first sub-structures on the first base substrate in the second direction Y may all be unequal or not exactly equal, and the widths of the orthographic projections of the plurality of second sub-structures on the first base substrate in the second direction Y may all be unequal or not exactly equal.

It should be noted that, as shown in FIGS. 2, 6, and 8, in the second direction Y, the total width H1 of the orthographic projection(s) of the first sub-structures 5-1 included in the first structure 5 on the first base substrate is the sum of the widths L7 of the orthographic projection(s) of the respective first sub-structures 5-1 included in the first structure 5 in the first direction Y on the first base substrate; and in the second direction Y, the total width H2 of the orthographic projection(s) of the sub-structures 6-1 included in the second structure 6 on the first base substrate is the sum of the widths L8 of the orthographic projections of the respective second sub-structures 6-1 included in the second structure 6 in the second direction Y on the first base substrate. In FIGS. 2 and 8, the first structure 5 includes one first sub-structure 5-1, and the second structure 6 includes one second sub-structure 6-1, i.e., H1=L7=H2=L8. In FIG. 6, the first structure 5 includes one first sub-structure 5-1, the second structure 6 includes two second sub-structures 6-1, and the second structure 6 includes two second sub-structures 6-1 with equal widths L8, then H1=L7=H2=2×L8.

It is noted that in the different first sub-electrodes, each first structure includes an equal number of first sub-structures, each second structure includes an equal number of second sub-structures, the width L7 of the orthographic projection of the first sub-structure included in each first structure on the first base substrate is equal, and the width L8 of the orthographic projection of the second sub-structure included in each second structure on the first base substrate is equal. In the different second sub-electrodes, each first structure includes an equal number of first sub-structures, each second structure includes an equal number of second sub-structures, the width L7 of the orthographic projection of the first sub-structure included in each first structure on the first base substrate is equal, and the width L8 of the orthographic projection of the second sub-structure included in each second structure on the first base substrate is equal. The width L7 of the orthographic projection of the first sub-structure included in the first structure of the first sub-electrode on the first base substrate and the width L7 of the orthographic projection of the first sub-structure included in the first structure of the second sub-electrode on the first base substrate may be equal or may not be equal, and the width L8 of the orthographic projection of the second sub-structure included in the second structure of the first sub-electrode on the first base substrate and the width L8 of the orthographic projection of the second sub-structure included in the second structure of the second sub-electrode on the first base substrate may be equal or may not be equal.

In some embodiments, as shown in FIG. 2, when the first structure 5 includes one first sub-structure 5-1, the second structure 6 includes one second sub-structure 6-1, and L7=L8, an edge of the first sub-structure 5-1 of the first structure 5 proximate to the pixel portion 402 is located in the same straight line as an edge of the second sub-structure 6-1 of the second structure 6 proximate to the pixel portion 402, and an edge of the first sub-structure 5-1 of the first structure 5 1 facing away from the pixel portion 402 is located in the same straight line as an edge of the second sub-structure 6-1 of the second structure 6 facing away from the pixel portion 402. Of course, as shown in FIG. 7, the edge of the first sub-structure 5-1 of the first structure 5 proximate to the pixel portion 402 is located in a different straight line from the edge of the second sub-structure 6-1 of the second structure 6 proximate to the pixel portion 402, and the edge of the first sub-structure 5-1 of the first structure 5 facing away from the pixel portion 402 is located in a different straight line from the edge of the second sub-structure 6-1 of the second structure 6 facing away from the pixel portion 402.

It should be noted that, in FIG. 7, the first sub-electrode 9 is taken as an example. In a specific implementation, in the second sub-electrode, the edge of the first sub-structure of the first structure proximate to the pixel portion is located in a different straight line from the edge of the second sub-structure of the second structure proximate to the pixel portion, and the edge of the first sub-structure of the first structure away from the pixel portion is located in a different straight line from the edge of the second sub-structure of the second structure away from the pixel portion.

In specific implementations, the relative positions of the first structure and the second structure may be set according to actual needs. For example, it may be set according to the wiring space.

It should be noted that, as shown in FIG. 2, L6 is a distance between an end of the first structure 5 away from the first sub-connection portion 4011 and an edge of the first opening area 301 in the first direction X; L5 is a distance between an end of the second structure 6 away from the first sub-connection portion 4011 and an edge of the first opening area 301 in the first direction X.

In particular embodiments, L6+L4 is greater than or equal to L9, and L3+L5 is greater than or equal to L10.

It should be noted that L6+L4 is greater than L9 and L3+L5 is greater than L10 as examples in FIG. 2. When L6+L4 is greater than L9, in the second direction, the width of the orthographic projection of the first sub-structure of the portion of the first structure outside of the first region in the first structure on the first base substrate may be equal to the width of the orthographic projection of the first sub-structure of the first region on the first base substrate, and, of course, the width of the orthographic projection of the first sub-structure of the portion of the first structure outside of the first region in the first structure on the first base substrate may not be equal to the width of the orthographic projection of the first sub-structure of the first region on the first base substrate, the width of the orthographic projection of the first sub-structure of the portion of the first structure outside of the first region in the first structure on the first base substrate may be greater than the width of the orthographic projection of the first sub-structure of the first region on the first base substrate, or the width of the orthographic projection of the first sub-structure of the portion of the first structure outside of the first region in the first structure on the first base substrate may be smaller than the width of the orthographic projection of the first sub-structure of the first region on the first base substrate. When L3+L5 is greater than L10, in the second direction, the width of the orthographic projection of the second sub-structure of the portion of the second structure outside of the second region in the second structure on the first base substrate may be equal to the width of the orthographic projection of the second sub-structure of the second region on the first base substrate, and, of course, the width of the orthographic projection of second first sub-structure of the portion of the second structure outside of the second region in the second structure on the first base substrate may not be equal to the width of the orthographic projection of the second sub-structure of the second region on the first base substrate, the width of the orthographic projection of the second sub-structure of the portion of the second structure outside of the second region in the second structure on the first base substrate may be greater than the width of the orthographic projection of the second sub-structure of the second region on the first base substrate, or the width of the orthographic projection of the second sub-structure of the portion of the second structure outside of the second region in the second structure on the first base substrate may be smaller than the width of the orthographic projection of the second sub-structure of the second region on the first base substrate.

In some embodiments, as shown in FIG. 2, in the first sub-electrode 9, the third structure 41 is electrically connected to the first structure 5, and the orthographic projection of the third structure 41 on the first base substrate 1 and the orthographic projection of the first opening area 301 on the first base substrate 1 do not overlap each other.

That is, in the array substrate provided in the embodiments of the present disclosure, the orthographic projection of the third structure on the first base substrate and the orthographic projection of the first opening area on the first base substrate do not overlap with each other, i.e., the first connection portion does not include portions connected to both sides of the first sub-connection portion in the second direction, so that, in the second direction, even if the second electrode is shifted, the overlapping area between the second electrode and the first electrode will not be affected, avoiding a rocking head pattern caused by different parasitic capacitances among the plurality of second electrodes.

In some embodiments, as shown in FIG. 2, one end of the third structure 41 facing away from one side of the first opening area 301 in an extension direction of the first structure 5 is electrically connected to the first structure 5.

Of course, in some embodiments, the third structure may also be electrically connected to the first structure at other regions of the first structure.

In some embodiments, as shown in FIGS. 2 and 8, in the first direction X, the length L6+L4 of the orthographic projection of the first structure 5 on the first base substrate is greater than the length L3+L5 of the orthographic projection of the second structure 6 on the first base substrate.

That is, in the array substrate provided by the embodiments of the present disclosure, in the first sub-electrode, the first sub-connection portion is connected to the pixel portion via the longer first structure, and the third structure.

In some embodiments, as shown in FIG. 3, in the first sub-electrode 9 and its corresponding thin-film transistor 2, the first structure 5, as well as the second pole S, are located on the same side of the first opening area 301 in the first direction X.

The orthographic projection of the first structure 5 on the first base substrate 1 overlaps with the orthographic projection of the second pole S on the first base substrate 1.

In some embodiments, in the second sub-electrode and its corresponding thin-film transistor, the first structure and the second pole are located on different sides of the first opening area in the first direction X.

It should be noted that in the related art, when the second electrode and the thin-film transistor electrically connected are located in the same column, the connection between the second electrode and the thin-film transistor is a short connection, i.e., the pixel portion and the first sub-connection portion are directly connected via the connection portion between the area between the pixel portion and the first sub-connection portion; and when the electrically connected second electrode and the thin-film transistor are located in different columns, the connection between the second electrode and the thin-film transistor is a long connection, i.e., the pixel portion and the first sub-connection portion need to be connected to the pixel portion via a connection portion spanning an adjacent sub-pixel column. The overlapping area of the connection portion of the short connection with the first electrode is much smaller than the overlapping area of the connection portion of the long connection with the first electrode, and thus the parasitic capacitance between the second electrode of the short connection and the first electrode and the parasitic capacitance between the second electrode of the long connection and the first electrode results in a large difference in the charging rate of the different second electrodes, which results in a difference in the luminance of the different sub-pixels, and a shaking of the head pattern easily occurs, affecting the user experience.

In the array substrate provided by the embodiments of the present disclosure, in the first sub-electrode, the first sub-connection portion is connected to the pixel portion through the longer first structure and the third structure, i.e., the first sub-connection portion in the first sub-electrode and the pixel portion are also connected through a long connection, which, compared to the short connection in the related art, raises the occupied area of the first connection portion, and thus raises the overlapping area between the first connection portion in the first sub-electrode and the first electrode, which is conducive to balancing the parasitic capacitance between the first sub-electrode and the first electrode and the parasitic capacitance between the second sub-electrode and the first electrode, avoiding differences in the brightness of different sub-pixels, avoiding a shaking of the head pattern, and improving the user experience.

In some embodiments, the orthographic projection of the pixel portion of the first sub-electrode on the first base substrate has a first overlapping area with the orthographic projection of the first electrode on the first base substrate, the orthographic projection of the pixel portion of the second sub-electrode on the first base substrate has a second overlapping area with the orthographic projection of the first electrode on the first base substrate; the orthographic projection of the first connection portion of the first sub-electrode on the first base substrate has a third overlapping area with the orthographic projection of the first electrode on the first base substrate, the orthographic projection of the first connection portion of the second sub-electrode on the first base substrate has a fourth overlapping area with the orthographic projection of the first electrode on the first base substrate; the first overlapping area is approximately equal to the second overlapping area, and the third overlapping area is approximately equal to the fourth overlapping area. Thereby, the overlapping area of the orthographic projection of the first sub-electrode on the first base substrate and the orthographic projection of the first electrode on the first base substrate is approximately equal to the overlapping area of the orthographic projection of the second sub-electrode on the first base substrate and the orthographic projection of the first electrode on the first base substrate, and the parasitic capacitance between the first sub-electrode and the first electrode and the parasitic capacitance between the second sub-electrode and the first electrode do not differ greatly, avoiding differences in the brightness of the different sub-pixels, avoiding a shaking of the head pattern, and improving the user experience.

It should be noted that the difference between the first overlapping area and the second overlapping area is within a reasonable process error, which can be considered that the first overlapping area is approximately equal to the second overlapping area; and the difference between the third overlapping area and the fourth overlapping area is within a reasonable process error, which can be considered that the third overlapping area is approximately equal to the fourth overlapping area.

In specific implementations, as shown in FIG. 2 and FIG. 8, the overlapping area(s) of the orthographic projection(s) of the first structure 5, the second structure 6 and the third structure 41 in the first sub-electrode 9 on the first base substrate and the orthographic projection of the first electrode 3 on the first base substrate is (are) equal to the overlapping area(s) of the orthographic projection(s) of the first structure 5, the second structure 6 and the fifth structure 42 in the second sub-electrode 11 on the first base substrate and the orthographic projection of the first electrode 3 on the first base substrate.

In specific implementations, in the case where the first structure includes one first sub-structure and the second structure includes one second sub-structure, for example, the line width of the first connection portion in the first sub-electrode, except for the first sub-connection portion, is, for example, 3 microns to 10 microns; and the line width of the first connection portion in the second sub-electrode, except for the first sub-connection portion, is, for example, 3 microns to 8 microns. The line width of the first connection portion in the first sub-electrode, except for the first sub-connection portion may or may not be the same as the line width of the first connection portion in the second sub-electrode, except for the first sub-connection portion.

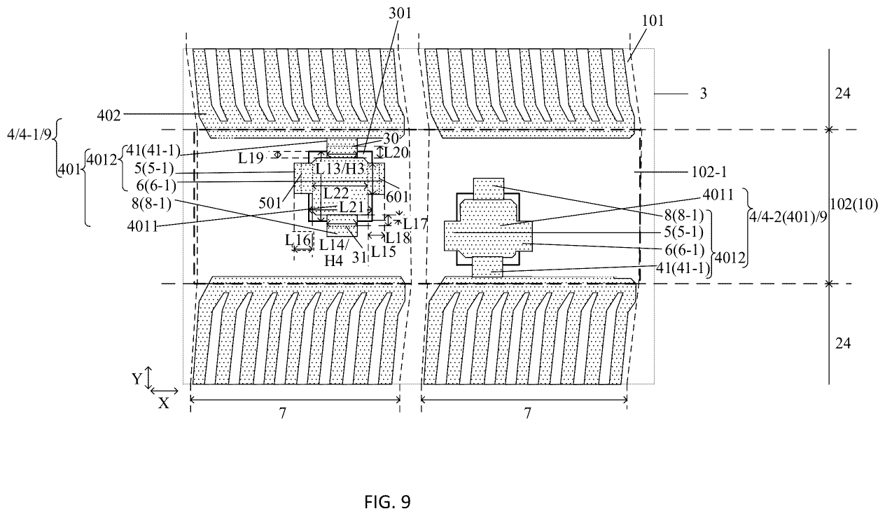

Alternatively, in some embodiments, as shown in FIG. 9, the orthographic projection of the third structure 41 on the first base substrate (not shown) overlaps with the orthographic projection of the first opening area 301 on the first base substrate.

In some embodiments, as shown in FIG. 9, the third structure 41 includes at least one third sub-structure 41-1 coupled in the second direction Y to the first sub-connection portion 4011.

It should be noted that, as shown in FIG. 9, for example, the third structure 41 includes one third sub-structure 41-1. Of course, in specific embodiments, the third structure may also include a plurality of third sub-structures, and the plurality of third sub-structures are arranged in the first direction.

In some embodiments, as shown in FIG. 9, in the first sub-electrode 9, in the first direction X, the length L16 of the orthographic projection of the first structure 5 on the first base substrate is equal to the length L15 of the orthographic projection of the second structure 6 on the first base substrate.

Of course, in specific embodiments, it is also possible to set up that in the first sub-electrode, in the first direction X, the length of the orthographic projection of the first structure on the first base substrate is not equal to the length of the orthographic projection of the second structure on the first base substrate.

In some embodiments, as shown in FIG. 9, in the first sub-electrode 9, the second sub-connection portion 4012 further includes a fourth structure 8; the fourth structure 8 includes at least one fourth sub-structure 8-1.

In the second direction Y, the third structure 41 and the fourth structure 8 are located on both sides of the first sub-connection portion 4011, respectively.

In the array substrate provided by the embodiments of the present disclosure, in the second direction Y, the third structure and the fourth structure are disposed on both sides of the first sub-connection portion. When there is a situation in which all the first sub-electrodes included in the array substrate are offset in the second direction Y due to a process deviation, i.e., the third structure and the fourth structure disposed on opposite two sides of the first sub-connection portion of the first sub-electrode in the second direction Y are offset, compared to the case where no offset occurs in the second direction Y, in the first connection portion of each first sub-electrode, the overlapping area of the orthographic projection of one of the third structure and the fourth structure on the first base substrate and the orthographic projection of the first electrode on the base substrate increases, and the overlapping area of the orthographic projection of the other one of the third structure and the fourth structure on the first base substrate and the orthographic projection of the first electrode on the base substrate decreases. Since the offset of the third structure and the fourth structure is the same, the changes in the overlapping areas of the orthographic projections of the third structure and the fourth structure and the first electrode on the first base substrate can be complementary. Even if the position of the first sub-electrode is offset due to process deviations, the parasitic capacitance between each first sub-electrode and the first electrode is still equal, avoiding significant differences in the charging rate of different second electrodes caused by different parasitic capacitances between the first sub-electrode and the first electrode. When the array substrate is applied to a display product, differences in the brightness of different sub-pixel areas can thus be avoided. When the user moves to view, it can avoid aggravation of the brightness difference, avoid the appearance of a head-shaking pattern, improve the display effect, and enhance the user experience.

In the array substrate provided in the embodiments of the present disclosure as shown in FIG. 9, opposite two sides of the first sub-connection portion 4011 of the first sub-electrode 9 in the first direction X and opposite two sides of the first sub-connection portion 4011 of the first sub-electrode 9 in the second direction Y are connected to the second sub-connection portion. Therefore, even if the position of the first sub-electrode is offset in the first direction X and/or the second direction Y due to process deviations, the parasitic capacitance between each first sub-electrode and the first electrode is still equal, avoiding significant differences in the charging rate of different second electrodes caused by parasitic capacitances between the different first sub-electrodes and the first electrode. When the array substrate is applied to a display product, differences in the brightness of different sub-pixel areas can thus be avoided. When the user moves to view, it can avoid aggravation of the brightness difference, avoid the appearance of a head-shaking pattern, improve the display effect, and enhance the user experience.

It should be noted that since in the second direction, both sides of the first sub-connection portion of the second sub-electrode are not connected to the second sub-connection portion, the parasitic capacitance between the second sub-electrode and the first electrode is not affected even if an offset in the second direction Y occurs.

In some embodiments, as shown in FIG. 9, in the first sub-electrode 9, the third structure 41 includes a third region 30 adjacent to the first sub-connection portion, and the fourth structure 8 includes a fourth region 31 adjacent to the first sub-connection portion.

In the second direction Y, a spacing L19 between the orthographic projection of the first sub-connection portion 4011 on the first base substrate and an orthographic projection of an edge of the first opening area 301 on a side of the first sub-connection portion 4011 toward the third structure on the first base substrate is less than a width L20 of an orthographic projection of the third region 30 on the first base substrate, and a spacing L17 between the orthographic projection of the first sub-connection portion 4011 on the first base substrate and an orthographic projection of an edge of the first opening area 301 on a side of the first sub-connection portion 4011 toward the fourth structure 8 on the first base substrate is less than a width L18 of an orthographic projection of the fourth region 31 on the first base substrate.

In the first direction X, the total width H3 of the orthographic projection of the third sub-structure 41-1 included in the third region 30 on the first base substrate is equal to the total width H4 of the orthographic projection of the fourth sub-structure 8-1 included in the fourth region 31 on the first base substrate.

It should be noted that, ideally, i.e., the first connection portion is not offset in the second direction Y, the overlapping area of the orthographic projection of the third sub-structure included in the third structure on the first base substrate and the orthographic projection of the first electrode on the first base substrate is S6, and the overlapping area of the orthographic projection of the fourth sub-structure included in the fourth structure on the first base substrate and the orthographic projection of the first electrode on the first base substrate is S7. Taking each second electrode included in the array substrate as an example with an upward offset of ΔL, and using FIG. 9 as an example, in FIG. 9, in the first sub-electrode 9 with the reference numeral 4-1, the overlapping area of the orthographic projection of the third sub-structure 41-1 included in the third structure 41 on the first base substrate and the orthographic projection of the first electrode 3 on the first base substrate is S6′=S6+H3×ΔL, the overlapping area of the orthographic projection of the fourth sub-structure 8-1 included in the fourth structure 8 on the first base substrate and the orthographic projection of the first electrode 3 on the first base substrate is S7′=S7-H4×ΔL, S6′+S7′=S6+H3×ΔL+S7-H4×ΔL. Since H3=H4, S6′+S7′=S6+S7; in the first sub-electrode 9 with the reference numeral 4-2, the overlapping area of the orthographic projection of the third sub-structure 41-1 included in the third structure 41 on the first base substrate and the orthographic projection of the first electrode 3 on the first base substrate is S6″=S6+H3×ΔL, the overlapping area of the orthographic projection of the fourth sub-structure 8-1 included in the fourth structure 8 on the first base substrate and the orthographic projection of the first electrode 3 on the first base substrate is S7′=S7+H4×ΔL, S6″+S7″=S6-H3×ΔL+S5+H4×ΔL. Since H3=H4, S4″+S7″=S6+S7. It can be seen that, even if the position of the first sub-electrode is shifted due to process deviations, the overlapping areas of the orthographic projections of the first connection portions of different first sub-electrodes and the first electrode on the base substrate are still equal, and the parasitic capacitances of each first sub-electrode and the first electrode are still equal, avoiding significant differences in the charging rate of different first sub-electrodes caused by parasitic capacitances between the different first sub-electrodes and the first electrode. When the array substrate is applied to a display product, differences in the brightness of different sub-pixel areas can thus be avoided. When the user moves to view, it can avoid aggravation of the brightness difference, avoid the appearance of a head-shaking pattern, improve the display effect, and enhance the user experience.

It should be noted that ideally, i.e., when the first connection portion of the first sub-electrode is not offset in the second direction Y, L20-L19 is not less than an offset error in the second direction Y, i.e., a relative offset between the first electrode and the second electrode due to the process deviation, and L18-L17 is not less than an offset error in the second direction Y. Ideally, L19=L17 in each first sub-electrode, and L19 is equal and L17 is equal in different first sub-electrodes. If the first sub-electrodes are offset in the second direction, in each first sub-electrode, L19 is not equal to L17, L19 is greater than L17 in some of the first sub-electrodes, L19 is less than L17 in the remaining part of the first sub-electrodes, L19 is not exactly equal in different first sub-electrodes, and L17 is not exactly equal in different first sub-electrodes. Ideally, L19=L17 is in a range of, for example, greater than or equal to 1.0 micron and less than or equal to 5 microns, and the offset error between the first electrode and the second electrode is in a range of, for example, greater than or equal to 1.5 microns and less than or equal to 4 microns. L20-L19, L18-L17 are in a range of, for example, greater than or equal to 2.5 microns and less than or equal to 10 microns.

In some embodiments, as shown in FIG. 9, in the first direction X, the maximum width L21 of the orthographic projection of the first sub-connection portion 4011 on the first base substrate is less than the width L22 of the orthographic projection of the first opening area 301 on the first base substrate, the maximum width L21 of the orthographic projection of the first sub-connection portion 4011 on the first base substrate is greater than the total width H3 of the orthographic projection of the third sub-structure 41-1 of the third region 30 on the first base substrate, and the maximum width L21 of the orthographic projection of the first sub-connection portion 4011 on the first base substrate is greater than the total width H4 of the orthographic projection of the fourth sub-structure 8-1 of the fourth region 31 on the first base substrate.

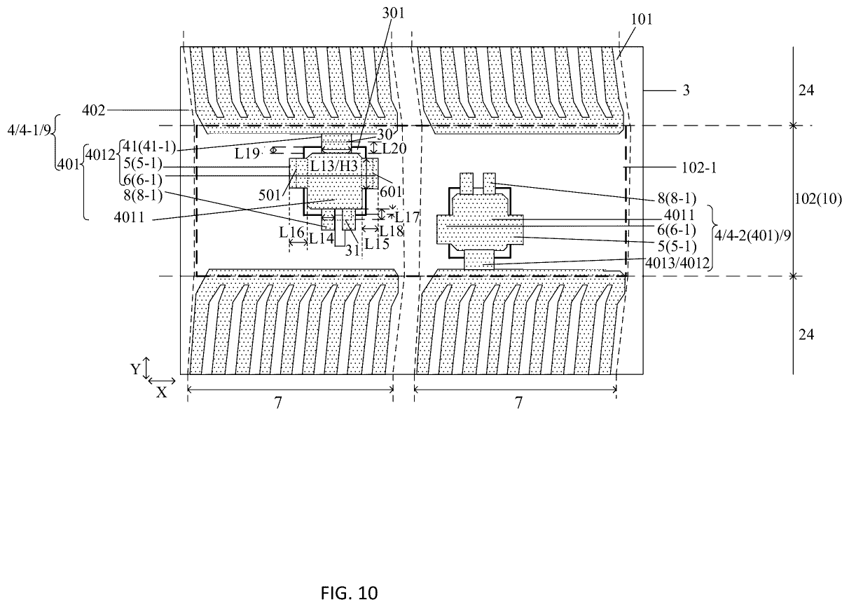

It should be noted that, as shown in FIG. 9, for example, the third structure 41 includes one third sub-structure 41-1, and the fourth structure 8 includes one fourth sub-structure 8-1. In particular embodiments, as shown in FIG. 10, the fourth structure 8 includes a plurality of fourth sub-structures 8-1, and the plurality of fourth sub-structures 8-1 are arranged along the first direction X. As shown in FIG. 10, the fourth structure 8 includes 2 fourth sub-structures 8-1 arranged along the first direction X. Of course, in specific implementations, the third structure may also include a plurality of third sub-structures.

In specific implementations, in the second direction Y, when the third structure includes the plurality of third sub-structures, the widths of the orthographic projections of the plurality of third sub-structures on the first base substrate in the first direction X may all be equal, and of course, the widths of the orthographic projections of the plurality of third sub-structures on the first base substrate in the first direction X may be unequal or not exactly equal. In the second direction Y, when the fourth structure includes a plurality of fourth sub-structures, the widths of the orthographic projections of the plurality of fourth sub-structures on the first base substrate in the first direction X may all be equal, and, of course, the widths of the orthographic projections of the plurality of fourth sub-structures on the first base substrate in the first direction X may be unequal or not exactly equal.

It should be noted that, as shown in FIGS. 9 and 10, in the first direction X, the total width H3 of the orthographic projection of the third sub-structure 41-1 included in the third structure 41 on the first base substrate refers to, in the first direction X, the sum of the width L13 of the orthographic projection of each third sub-structure 41-1 included in the third structure 41 on the first base substrate; and in the first direction X, the total width H4 of the orthographic projection of the fourth sub-structure 8-1 included in the fourth structure 8 on the first base substrate refers to, in the first direction X, the sum of the width L14 of the orthographic projection of each fourth sub-structure 8-1 included in the fourth structure 8 on the first base substrate. In FIG. 9, the third structure 41 includes one third sub-structure 41-1, the fourth structure 8 includes one fourth sub-structure 8-1, i.e., H3=L13=H4=L14. In FIG. 10, the third structure 41 includes one third sub-structure 41-1, the fourth structure 8 includes two fourth sub-structures 8-1, and the fourth structure 8 includes two second sub-connection portions 4012 of equal width L14, then H3=L13=H4=2×L14.

It should be noted that, in different first sub-electrodes, each of the third structures includes an equal number of third sub-structures, each of the fourth structures includes an equal number of fourth sub-structures, each of the third structures includes an equal width L13 of the third sub-structures in the orthographic projection on the first base substrate, and each of the fourth structures includes an equal width L14 of the fourth sub-structures in the orthographic projection on the first base substrate.

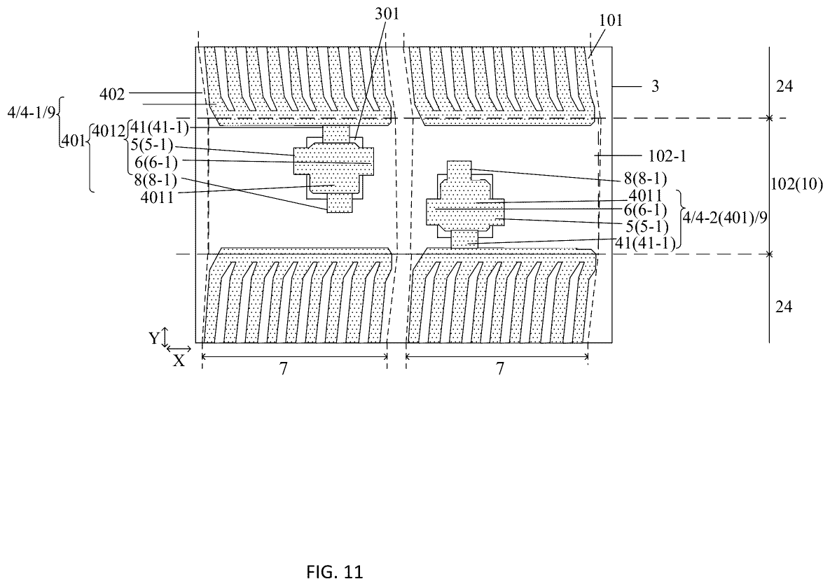

In some embodiments, as shown in FIG. 9, when the third structure 41 includes one third sub-structure 41-1, the fourth structure 8 includes one fourth sub-structure 8-1, and L13=L14, the edge, proximate to the first structure 5, of the third sub-structure 41-1 of the third structure 41 is located in the same straight line as the edge, proximate to the first structure 5, of the fourth sub-structure 8-1 of the fourth structure 8, and the edge, facing away from the first structure 5, of the third sub-structure 41-1 of the third structure 41 is located in the same straight line as the edge, facing away from the first structure 5, of the fourth sub-structure 8-1 of the fourth structure 8. Of course, as shown in FIG. 11, the edge, proximate to the first structure 5, of the third sub-structure 41-1 of the third structure 41 is located in a different straight line from the edge, proximate to the first structure 5, of the fourth sub-structure 8-1 of the fourth structure 8, and the edge, facing away from the first structure 5, of the third sub-structure 41-1 of the third structure 41 is located in a different straight line from the edge, facing away from the first structure 5, of the fourth sub-structure 8-1 of the fourth structure 8.

In specific implementations, the relative positions of the third structure and the fourth structure may be set according to actual needs. For example, it may be set according to the wiring space.

It should be noted that, when the first structure includes one first sub-structure, and the second structure includes one second sub-structure, as shown in FIG. 9, for example, in the second direction Y, the width of the orthographic projection of the first sub-structure included in the first structure on the first base substrate and the width of the orthographic projection of the second sub-structure included in the second structure on the first base substrate are both smaller than the width of the orthographic projection of the first sub-connection portion on the first base substrate. In particular embodiments, it may be provided that in the second direction Y, the width of the orthographic projection of the first sub-structure included in the first structure on the first base substrate and the width of the orthographic projection of the second sub-structure included in the second structure on the first base substrate are both equal to the width of the orthographic projection of the first sub-connection portion on the first base substrate. In the second direction Y, the width of the orthographic projection of the first sub-structure included in the first structure on the first base substrate, the width of the orthographic projection of the second sub-structure included in the second structure on the first base substrate, and the width of the orthographic projection of the first sub-connection portion on the first base substrate are, for example, greater than or equal to 3 microns and less than or equal to 10 microns.

In specific implementations, in the second direction Y, the width of the orthographic projection of the third structure on the first base substrate and the width of the orthographic projection of the fourth structure on the first base substrate may be or may not be equal.

In specific implementations, in the second direction Y, the width of the orthographic projection of the third structure on the first base substrate is greater than or equal to L20, and the width of the orthographic projection of the fourth structure on the first base substrate is greater than or equal to L18. In FIG. 9, for example, the width of the orthographic projection of the third structure on the first base substrate is greater than L20, and the width of the orthographic projection of the fourth structure on the first base substrate is greater than L18.

In specific implementations, the setting of the first sub-electrode as shown in FIGS. 9 to 11 can still realize that the third overlapping area and the fourth overlapping area are approximately equal. For example, the overlapping area(s) of the orthographic projection(s) of the third structure, the fourth structure, the second structure, and the first structure in the first sub-electrode on the first base substrate and the orthographic projection of the first electrode on the first base substrate is (are) equal to the overlapping area(s) of the orthographic projection(s) of the fifth structure, the second structure, and the first structure in the second sub-electrode on the first base substrate and the orthographic projection of the first electrode on the first base substrate.

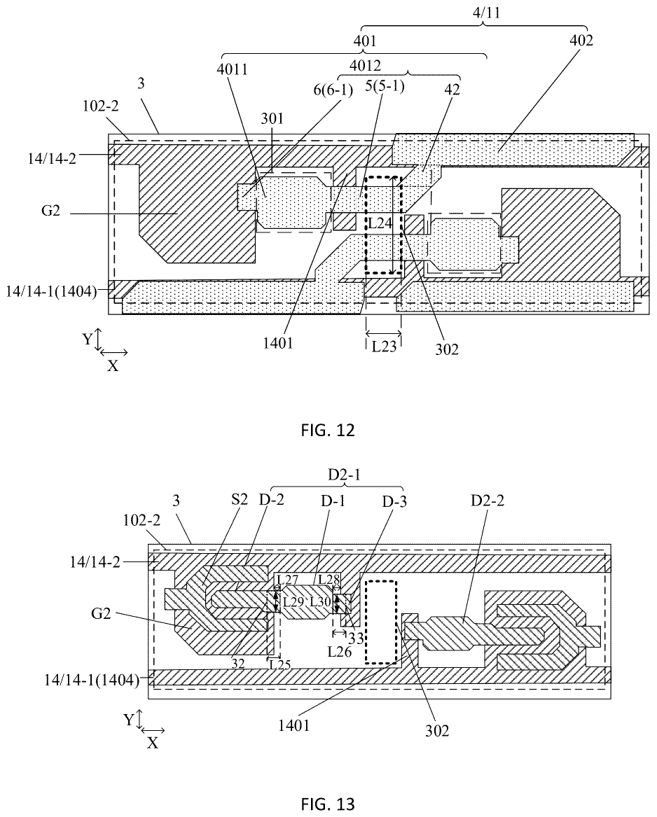

In some embodiments, as shown in FIG. 12, the first electrode 3 further includes a plurality of second opening areas 302 disposed in the wiring areas 102. The orthographic projection of the second opening area 302 on the first base substrate overlaps with the orthographic projection of the first connection portion 401 of the second sub-electrode 11 on the first base substrate 1.

In the array substrate provided in the embodiments of the present disclosure, the first electrode further includes a second opening area corresponding to the first connection portion of the second sub-electrode, so as to reduce the overlapping area between the second sub-electrode and the first electrode, which is conducive to realizing that the overlapping area of the first sub-electrode with the first electrode is the same as the overlapping area of the second sub-electrode with the first electrode.

In specific implementations, when the first electrode includes a second opening area corresponding to the second sub-electrode, the first connection portion of the first sub-electrode may be adopted in any of FIG. 2, FIG. 4, FIGS. 6 to 7, and FIGS. 9 to 11.

In specific implementations, as shown in FIG. 12, the orthographic projection of the second sub-connection portion 4012 included in the first structure 5 of the second sub-electrode 11 on the first base substrate overlaps with the orthographic projection of the second opening area 302 on the first base substrate. The orthographic projection of the first structure 5 included in the second sub-connection portion 4012 on the first base substrate overlaps with the orthographic projection of the second opening area 302 on the first base substrate.

In some embodiments, as shown in FIG. 12, the orthographic projection of the second opening area 302 on the first base substrate and the orthographic projection of the scan line 14 on the first base substrate do not overlap each other. Thereby, it can be avoided that the second opening exposes the scan line resulting in parasitic capacitance of the scan line with the second sub-electrode.

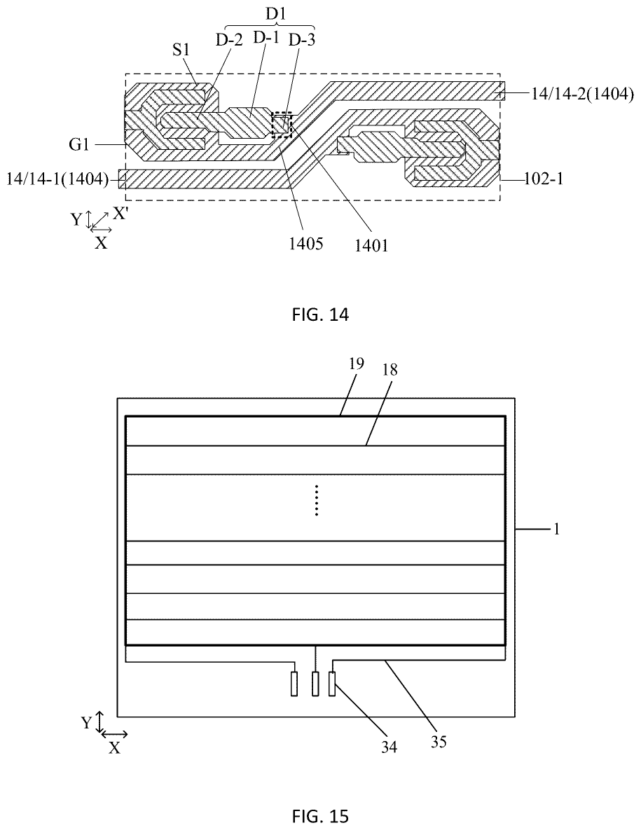

In some embodiments, as shown in FIGS. 13 and 14, the scan line 14 includes a first compensation portion 1401 corresponding to the thin-film transistor 2.

The first pole D of the thin-film transistor 2 includes: a first portion D-1, and a second portion D-2 and a third portion D-3 disposed on both sides of the first portion D-1 in the first direction X, respectively.

The orthographic projection of the first portion D-1 on the first base substrate 1 falls into the orthographic projection of a region between the third pole G and the first compensation portion 1401 on the first base substrate 1, the orthographic projection of the second portion D-2 on the first base substrate 1 overlaps with the orthographic projection of the third pole G on the first base substrate 1, and the orthographic projection of the third portion D-3 on the first base substrate 1 overlaps with the orthographic projection of the first compensation portion 1401 on the first base substrate 1.

It should be noted that, since the first pole (i.e., the drain electrode) of the thin-film transistor has an overlap with the film layer (hereinafter referred to as the first conductive layer) where the third pole, i.e., the gate electrode, and the scan line are located, a capacitance Cgs is formed between the first pole and the first conductive layer. If all the first poles included in the array substrate offset in the first direction due to process deviations, taking rightward offset as an example, the overlapping area between the first pole and the first conductive layer in some thin film transistors will increase, and the overlapping area between the first pole and the first conductive layer in some thin film transistors will decrease, which will result in different capacitors Cgs formed between the first pole and the first conductive layer in different thin film transistors.

In the array substrate provided in the embodiments of the present disclosure, the scan line includes a first compensation portion, the first pole includes a second portion having an overlap with the third pole and a third portion having an overlap with the first compensation portion, the capacitance formed between the second portion and the third pole is Cgs1, and the capacitance formed between the third portion and the first compensation portion is Cgs2. If all the first poles included in the array substrate offset in the first direction due to process deviations, for each thin-film transistor and the scan line electrically connected to the thin-film transistor, if the overlapping area between the second portion and the third pole increases, the overlapping area between the third portion and the first compensation portion decreases, and if the overlapping area between the second portion and the third pole decreases, the overlapping area between the third portion and the first compensation portion increases. That is, one of Cgs1 and Cgs2 increases and the other decreases, which can compensate for the effect of the capacitance Cgs formed between the first pole and the first conductive layer due to the process deviation, avoiding a different capacitance Cgs formed between the different first poles and the first conductive layer, and avoiding affecting the display effect.

It should be noted that a region corresponding to the second thin-film transistor 2-2 is illustrated in FIG. 13, and a region corresponding to the first thin-film transistor 2-1 is illustrated in FIG. 14.

In some embodiments, in the second direction Y, the width of the orthographic projection of the third portion on the first base substrate is equal to the width of the orthographic projection of the side of the second portion near the first portion on the first base substrate.

Specifically, taking the second thin-film transistor as an example, as shown in FIG. 13, the second portion D-2 includes a fifth region 32 adjacent to the first portion D-1, and the third portion D-3 includes a sixth region 33 adjacent to the first portion D-1, and in the second direction Y, the width L29 of the orthographic projection of the fifth region 32 on the first base substrate is equal to the width L30 of the orthographic projection of the sixth region 33 on the first base substrate.

It should be noted that ideally, i.e., when the first pole is not offset in the first direction X, the overlapping area of the orthographic projection of the second portion on the first base substrate and the orthographic projection of the third pole on the first base substrate is S8, and the overlapping area of the orthographic projection of the third portion on the first base substrate and the orthographic projection of the first compensation portion on the first base substrate is S9. For example, each first pole of the array substrate is shifted leftward by ΔL, and taking FIG. 13 as an example, as shown in FIG. 13, in the first pole D2 labeled D2-1 in the accompanying drawing, the overlapping area of the orthographic projection of the second portion D-2 on the first base substrate (not shown) and the orthographic projection of the third pole G2 on the first base substrate is S8′=S8+L29×ΔL, and the overlapping area of the orthographic projection of the third portion D-3 on the first base substrate and the orthographic projection of the first compensation portion 1401 on the first base substrate is S9′=S9-L30×ΔL, S8′+S9′=S8+L29×ΔL+S9-L30×ΔL, and since L29=L30, S8′+S9′=S8+S9; in the first pole D2 labeled D2-2 in the accompanying drawing, the overlapping area of the orthographic projection of the second portion D-2 on the first base substrate and the orthographic projection of the third pole G2 on the first base substrate is S8″=S8-L29×ΔL, and the overlapping area of the orthographic projection of the third portion D-3 on the first base substrate and the orthographic projection of the first compensation portion 1401 on the first base substrate is S9″=S9+L30×ΔL, S8″+S9″=S8-L29×ΔL+S9+L30×ΔL, and since L29=L30, S8″+S9″=S8+S9. It can be seen that even if the position of the first pole is offset due to the process deviation, the overlapping areas of the orthographic projections of different first poles and the first conductive layer where the third pole and the scan line are located on the base substrate are still equal, and the capacitances Cgs between each first pole and the first conductive layer where the third pole and the scan line are located are still equal, to avoid affecting the display effect due to the different capacitances Cgs formed between different first poles and the first conductive layer where the third pole and the scan line are located.

In some embodiments, in the second direction Y, the width of the orthographic projection of the first portion on the first base substrate is greater than the width of the orthographic projection of the fifth region on the first base substrate, and the width of the orthographic projection of the first portion on the first base substrate is greater than the width of the orthographic projection of the sixth region on the first base substrate.

It should be noted that, in FIG. 13, for example, the edge of the fifth region 32 extending along the first direction X and the edge of the sixth region 33 extending along the first direction X are not located in the same straight line. Of course, in specific embodiments, it is also possible to set up that the edge of the fifth region 32 extending along the first direction X and the edge of the sixth region 33 extending along the first direction X on the same side are located in the same straight line.

In some embodiments, L29, L30 are, for example, greater than or equal to 2 microns and less than or equal to 8 microns.

In some embodiments, as shown in FIG. 13, in the first direction X, a width L25 of the orthographic projection of the fifth region 32 on the first base substrate is greater than a distance L27 between the orthographic projection of the first portion D-1 on the first base substrate and the orthographic projection of the third pole G2 on the first base substrate, and a width L26 of the orthographic projection of the sixth region 33 on the first base substrate is greater than a distance L28 between the orthographic projection of the first portion D-1 on the first base substrate and the orthographic projection of the first compensation portion 1401 on the first base substrate.

It should be noted that ideally, i.e., in the case where the first pole is not offset in the first direction X, L25-L27 are not less than an offset error in the first direction X, i.e., a relative offset amount of the first pole from the first conductive layer due to the process deviation, and L26-L28 are not less than the offset error in the first direction X. Ideally, L27=L28 in each first pole, and L27 is equal and L28 is equal in different first poles. If the second electrodes are offset in the first direction, in each second electrode, L27 is not equal to L28, L27 is greater than L28 in some of the second electrodes, L27 is less than L28 in the remaining part of the second electrodes, L27 is not exactly equal in the different second electrodes, and L28 is not exactly equal in the different second electrodes. Ideally, L27=L28 is in a range of, for example, greater than or equal to 2.0 microns and less than or equal to 5.0 microns, and the offset error of the first electrode from the first conductive layer is, for example, greater than or equal to 0.5 microns and less than or equal to 2.0 microns. L25-L27, L26-L28 are, for example, greater than or equal to 2.5 microns and less than or equal to 10 microns.

In some embodiments, as shown in FIG. 14, in the first sub-area 102-1, the scan line 14 includes: a first portion 1404 extending along a first direction X, and a second portion 1405 extending along a third direction X′ and connected to the first portion 1404; the third direction X′ intersects with both the first direction X and the second direction Y; the first compensation portion 1401 is disposed on a side of the second portion 1405 toward the third pole G.

It should be noted that, if the first electrode does not include a second opening area, the pattern of scan lines in the second sub-area may also be as shown in FIG. 14. In some embodiments, in the second sub-area, the scan line includes: a second portion extending along a first direction X, and a third portion extending along a third direction X′ and connected to the second portion; the third direction X′ intersects with both the first direction X and the second direction Y; and the first compensation portion is located on a side of the third portion toward the third pole.

In some embodiments, as shown in FIG. 13, the first electrode 3 includes a second opening area 302, and in the second sub-area 102-2, the scan line 14 includes: a second portion 1402 extending along the first direction X; the first compensation portion 1401 is connected to the second portion 1402 in the second direction Y, and in the second direction Y, the first compensation portion 1401 and the third pole are located on the same side of the second portion 1402.

In some embodiments, as shown in FIG. 13, in the second sub-area 102-2, the orthographic projection of the second opening area 302 on the first base substrate 1 does not overlap with the scan line 14, and the orthographic projection of the second opening area 302 on the first base substrate 1 falls into an orthographic projection of a region between two adjacent first compensation portions 1401 on the first base substrate 1.

In some embodiments, in at least a portion of the second sub-area, the second opening areas 302 corresponding to two first connection portions 401 are integrally connected, as shown in FIG. 12.

In some embodiments, as shown in FIG. 12, the orthographic projection of the second opening area 302 on the first base substrate (not shown) has a width L23 in the first direction X greater than or equal to 5 microns and less than or equal to 15 microns, and the orthographic projection of the second opening area 302 on the first base substrate has a width L24 in the second direction Y greater than or equal to 10 microns and less than or equal to 40 microns.

In some embodiments, the first electrode includes a plurality of slit units, or as shown in FIG. 5, the first portion includes a slit unit(s) 15; an orthographic projection of the slit unit 15 on the first base substrate 1 overlaps with the sub-pixel area 101.

The slit unit 15 includes: a first sub-unit 1501 and a second sub-unit 1502 alternately arranged in a second direction Y; the first sub-unit 1501 includes a plurality of first slits 16 extending along a fourth direction X″ and arranged along the first direction X, and the second sub-unit 1502 includes a plurality of second slits 17 extending along a fifth direction X″ and arranged along the first direction X; the fourth direction X″ intersects with the fifth direction X″, the fourth direction X″ intersects with both the first direction X and the second direction Y; and the fifth direction X″″ intersects with both the first direction X and the second direction Y.

The orthographic projection of the first electrode wire 18 on the first base substrate 1 overlaps with an orthographic projection of a location where the first sub-unit 1501 is connected to the second sub-unit 1502 on the first base substrate 1.

In the array substrate provided in the embodiments of the present disclosure, the first electrode wire electrically connected to the first electrode is disposed in a region corresponding to the location where the first sub-unit is connected to the second sub-unit, i.e., the first electrode wire is disposed in a corner dark area in the middle of the sub-pixel to avoid affecting the opening rate of the sub-pixel.

In some embodiments, a line width of the first electrode wire, i.e., a width in the second direction, is greater than or equal to 2 micrometers and less than or equal to 8 micrometers.

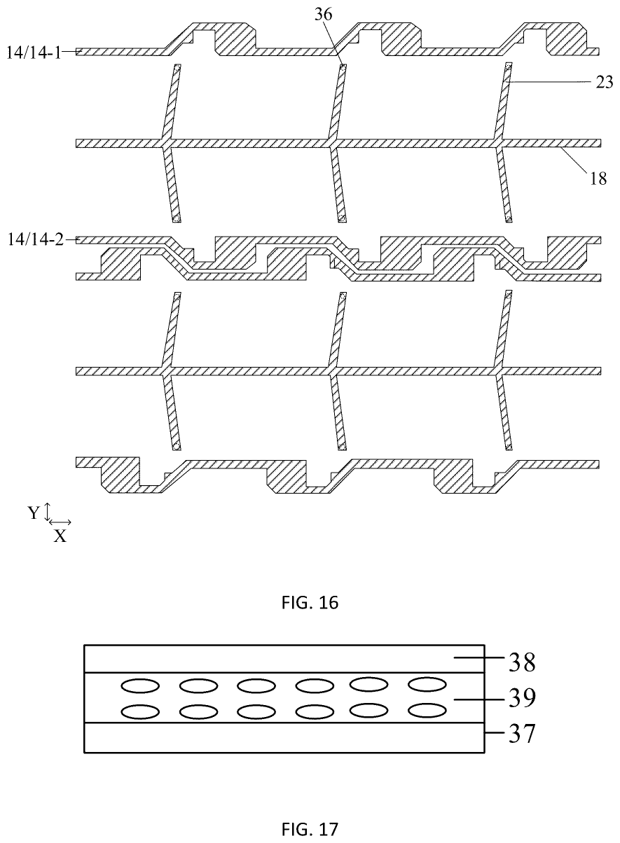

In particular embodiments, as shown in FIG. 5, the first electrode wire 18 is connected to the second electrode wire 23, and the second electrode wire 23 is connected to the first electrode (not shown) through a first through hole 36. The pattern of the first electrode wire 18 and the second electrode wire 23 in FIG. 5 is shown in FIG. 16.

In specific embodiments, as shown in FIG. 3, the thin-film transistor 2 further includes: an active layer 201, a gate insulating layer 26, and an interlayer insulating layer 27. As shown in FIG. 3, the array substrate further includes a first protective layer 29 between the first electrode 3 and the second electrode 4, a planarization layer 28 between the first electrode 3 and the first pole D and the second pole S of the thin-film transistor 2, and a buffer layer 25 between the first base substrate 1 and the thin-film transistor 2. FIG. 3 exemplifies the thin-film transistor as a top-gate structure. Of course, the thin-film transistor may also be a bottom gate structure or the like in a specific implementation.

In specific embodiments, when the thin-film transistor is the top-gate structure, the first pole and the second pole are electrically connected to a conductorization region of the active layer through a first through hole penetrating the interlayer insulating layer and the gate insulating layer, respectively. The insulating layers between the second electrode wire and the first electrode are a planarization layer, an interlayer insulating layer, and a gate insulating layer, and the first electrode is electrically connected to the second electrode wire through a first through hole penetrating the planarization layer, the interlayer insulating layer, and the gate insulating layer.

In specific embodiments, when the thin-film transistor is the bottom gate structure, the active layer is disposed on a side of the third pole facing away from the buffer layer, and the gate insulating layer is between the active layer and the third pole, and the second pole and the first pole are directly lapped with the active layer of the thin-film transistor. The insulating layers between the second electrode wire and the first electrode are a planarization layer and a gate insulating layer, and the first electrode is electrically connected to the second electrode wire through a first through hole penetrating the planarization layer and the gate insulating layer.

In some embodiments, as shown in FIG. 5, an orthographic projection of the first through hole 36 on the first base substrate falls into an orthographic projection of the second electrode wire 23 on the first base substrate; and the orthographic projection of the first through hole 36 on the first base substrate falls into an orthographic projection of an end of the second electrode wire 23 away from the first electrode wire 18 on the first base substrate.

In the array substrate provided in the embodiments of the present disclosure, the second electrode wire is located in a region between two adjacent sub-pixel columns, and the second electrode wire is arranged in alternating rows with the data line, so that the region where the data line is not provided can be reasonably utilized to realize the second electrode wire is electrically connected to the first electrode through the first through hole at the same time to avoid affecting the transmittance rate of the sub-pixel, and when the array substrate is applied to the liquid crystal product, the alignment precision of the box can be ensured as well.

In some embodiments, the first through hole 36 has a circular orthographic projection on the first base substrate. The diameter of the circle is, for example, greater than or equal to 3 microns and less than or equal to 10 microns.

In some embodiments, as shown in FIG. 15, the array substrate further includes: a peripheral electrode wire 19. An orthographic projection of the peripheral electrode wire 19 on the first base substrate 1 encloses a plurality of sub-pixel areas (not shown) and a plurality of wiring areas (not shown).

At least some of the plurality of first electrode wires 18 are electrically connected to the peripheral electrode wires 19.

For example, both ends of each first electrode wire 18 in the extension direction are electrically connected to the peripheral electrode wire 19.

In the embodiments of the present disclosure, the array substrate further includes peripheral electrode wires. The peripheral electrode wires enclose a plurality of sub-pixel areas and a plurality of first regions, i.e., the peripheral electrode wires are disposed in a peripheral area of the array substrate. When the array substrate is applied to a display product, the peripheral area corresponds to a non-display area of the display product. The peripheral connection lead is electrically connected to the first electrode wire, so that the impedance of the signal line electrically connected to the first electrode can be reduced without affecting the display or losing the resolution of the display product, thereby reducing the line width of the peripheral electrode wire and the size of the peripheral area, which is conducive to the realization of a narrow bezel display.

In some embodiments, the line width of the peripheral electrode wire is greater than or equal to 40 microns and less than or equal to 300 microns.

In some embodiments, the array substrate further includes a plurality of bonding terminals bound to a flexible circuit board, and some of the bonding terminals in the plurality of bonding terminals are electrically connected to the peripheral electrode wire. For example, as shown in FIG. 15, the array substrate further includes a plurality of connection leads 35 electrically connected to the peripheral electrode wires 19 and the bonding terminals 34.

In some embodiments, as shown in FIG. 5, the orthographic projection of the pixel portion 402 on the first base substrate 1 has an overlap with the orthographic projection of the scan line 14 on the first base substrate 1.

In the array substrate provided in the embodiments of the present disclosure, the pixel portion extends to the wiring area and has an overlapping region with the scan line, which can increase the setting space of the first slit and the second slit included in the pixel portion in the second direction, i.e., the length of the first slit and the second slit can be increased, which can thereby increase the transmittance rate of the sub-pixels.

In particular embodiments, the base substrate is, for example, a glass substrate. The material of the active layer may be amorphous silicon (a-Si), polycrystalline silicon (poly), oxide (such as indium gallium zinc oxide (IGZO)), and the like. The materials of the first pole, the second pole, the third pole, the scan line, the data line, the first electrode wire, the second electrode wire, and the peripheral electrode wire may include copper (Cu), molybdenum (Mo), aluminum (Al), titanium (Ti), chromium (Cr), nickel (Ni), and other metals, and the first pole, the second pole, the third pole, the scan line, the data line, the first electrode wire, the second electrode wire, and the peripheral electrode wire may be a single-layer or a laminated structure. For example, the laminated structure is a stacked layer structure including a titanium metal layer/aluminum metal layer/titanium metal layer. In specific implementations, the third pole, the scan line, the first electrode wire, the second electrode wire, and the peripheral electrode wire are set up in the same layer, the first conductive layer, the first pole, the second pole, the data line are set up in the same layer as the second conductive layer, and the first conductive layer and the second conductive layer may be of different materials, e.g., the first conductive layer is of the material of Cu, and the second conductive layer is of the material of Al. Alternatively, the first conductive layer and the second conductive layer may be of the same material, for example, the materials of the first conductive layer and the material of the second conductive layer are Cu. The materials of the first electrode and the second electrode are the same, for example, a transparent conductive material such as indium tin oxide (ITO), indium zinc oxide (IZO), and the like. The materials of the buffer layer, the gate insulating layer, the interlayer insulating layer, and the first protective layer are, for example, at least one of silicon nitride and silicon oxide. The material of the planarization layer is, for example, PI.

Based on the same inventive concept, the embodiments of the present disclosure further provide a display panel, as shown in FIG. 17, the display panel including:
the array substrate 37 provided by the embodiments of the present disclosure;
an opposite substrate 38, disposed opposite to the array substrate 37;
a liquid crystal layer 39, between the array substrate 37 and the opposite substrate 38.

It should be noted that since the principle of solving problems by the display device is similar to the principle of solving problems by the above-described array substrate, the implementation of the display device can be seen in the embodiments of the above-described array substrate, and the repetition will not be repeated.

In some embodiments, the array substrate includes a plurality of data lines; the opposite substrate includes:
a second base substrate;
a plurality of spacers disposed on one side of the second base substrate facing the liquid crystal layer.

In specific implementations, the side of the array substrate proximate to the liquid crystal layer and the side of the opposite substrate proximate to the liquid crystal layer are further provided with an alignment layer(s).

In specific embodiments, the opposite substrate includes the second base substrate. In some embodiments, the opposite substrate further includes a black matrix and a color resist on the side of the second base substrate facing the liquid crystal layer. The black matrix has an opening area and the color resist is disposed within the opening area; the spacer is disposed on the side of the black matrix facing the liquid crystal layer.

In particular embodiments, an orthographic projection of the black matrix on the array substrate falls into the wiring area. The color resist is in one-to-one correspondence with the sub-pixel area, and an orthographic projection of the color resist on the array substrate falls into the sub-pixel area. The display panel includes sub-pixels that correspond one-to-one with the sub-pixel areas. The sub-pixels include red sub-pixels, blue sub-pixels, and green sub-pixels. Accordingly, the color resist includes a red color resist corresponding to the red sub-pixel, a blue color resist corresponding to the blue sub-pixel, and a green color resist corresponding to the green sub-pixel.

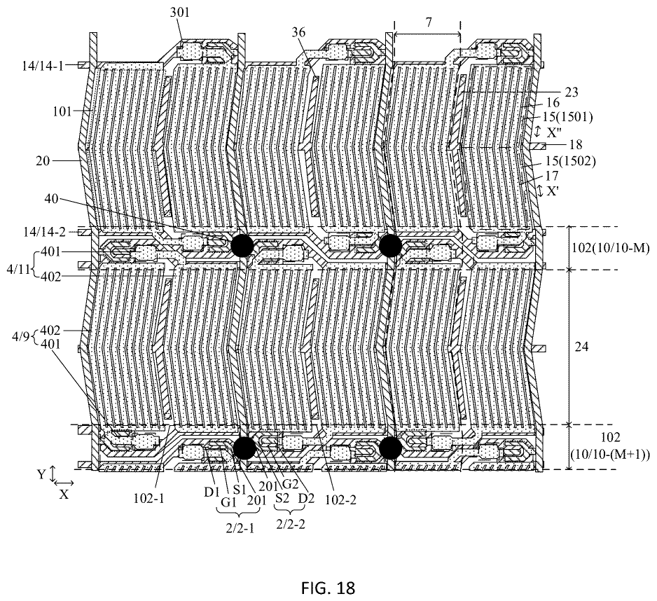

In some embodiments, as shown in FIG. 18, an orthographic projection of the spacer 40 on the first base substrate falls into the wiring area 102, and the orthographic projection of the spacer 40 on the first base substrate has an overlap with an orthographic projection of the data line 20 on the first base substrate.

In the display panel provided by the embodiments of the present disclosure, the orthographic projection of the spacer on the first base substrate falls into the wiring area, and the orthographic projection of the spacer on the first base substrate has an overlap with the orthographic projection of the data line on the first base substrate, i.e., the orthographic projection of the spacer on the first base substrate has an overlap with a region between two thin-film transistors. Since the insulating layer below the first electrode is the planarization layer, and the planarization layer is usually an organic film layer with a thickness greater than or equal to 1.5 micrometers and less than or equal to 4 micrometers, it can effectively fill in the breakage difference at different locations of the thin-film transistors, so that the spacer having an overlap in the area between the spacer and the two thin-film transistors in the wiring area does not affect the breakage difference of the liquid crystal panel. Moreover, the data lines as well as the thin-film transistors all correspond to an area covered by the black matrix, the orthographic projection of the spacer on the first base substrate and the orthographic projection of the data lines on the first base substrate have an overlap, and the orthographic projection of the spacer on the first base substrate overlaps with the region between the two thin-film transistors, so the area covered by the black matrix can be utilized, so that the influence of the spacer on the opening rate of the sub-pixels is smaller, to thereby improve the transmittance rate of the sub-pixel.

In specific implementations, the shape of the orthographic projection of the spacer on the first base substrate may be a circle, an ellipse, a hexagon, and the like. The maximum width of the orthographic projection of the spacer on the first base substrate in the first direction or the second direction is, for example, greater than or equal to 9 micrometers and less than or equal to 25 micrometers.

Embodiments of the present disclosure provide a display device, the display device including the display panel provided by the embodiments of the present disclosure.

In some embodiments, in the above-described display device provided by the embodiments of the present disclosure, the display device may also include a backlight module disposed on a light-entry side of the array substrate, and the backlight module may be a straight-down backlight module or a side-entry backlight module.

In specific implementations, the side-entry backlight module may include a light bar, a cascade of reflective sheets, a light guide plate, a diffusion sheet, a prism group, and the like, with the light bar disposed on one side of the thickness direction of the light guide plate. The straight-down backlight module may include a matrix light source, a reflective sheet, a diffusion plate, and a brightening film, etc., cascadingly disposed on the light output side of the matrix light source, and the reflective sheet includes an through hole positively disposed with the position of each lamp bead in the matrix light source. The lamp beads in the light bar and the lamp beads in the matrix light source may be light-emitting diodes (LEDs), such as miniature light-emitting diodes (Mini LEDs, Micro LEDs, etc.). Sub-millimeter scale or even micrometer scale miniature light-emitting diodes and organic light-emitting diodes (OLEDs) belong to the same self-luminous devices. Like organic light-emitting diodes, they have a series of advantages such as high brightness, ultra-low latency, and large viewing angle. And because the inorganic light-emitting diode light is based on the nature of a more stable, lower resistance of the metal semiconductor to achieve light, so it is based on organic material to achieve light-emitting organic light-emitting diode, has a lower power consumption, more resistant to high and low temperatures, the advantages of a longer service life. And when the micro light-emitting diode is used as a backlight source, a more precise dynamic backlight effect can be achieved, which can effectively improve the brightness and contrast of the screen while also solving the glare phenomenon caused by the traditional dynamic backlight between the bright and dark areas of the screen and optimizing the visual experience.

In some embodiments, the above display device provided by the embodiments of the present disclosure may be: a projector, a 3D printer, a virtual reality device, a cellular phone, a tablet computer, a television set, a monitor, a laptop computer, a digital photo frame, a navigator, a smartwatch, a fitness wristband, a personal digital assistant, and any other product or component with a display function. Optionally, the display device provided in the present disclosure includes, but is not limited to, components such as an RF unit, a network module, an audio output & input unit, a sensor, a display unit, a user input unit, an interface unit, and a control chip. Optionally, the control chip is a central processor, a digital signal processor, a system-on-chip (SoC), and the like. For example, the control chip may also include a memory, and may also include a power supply module and the like, and the power supply as well as the signal input and output functions are realized through additionally provided wires, signal lines, and the like. For example, the control chip may also include hardware circuits, computer executable codes, and the like. The hardware circuitry may include conventional very large scale integration (VLSI) circuits or gate arrays as well as existing semiconductors such as logic chips, transistors, and other discrete components; the hardware circuitry may also include field programmable gate arrays, programmable array logic, programmable logic devices, and the like. In addition, it is understood by those skilled in the art that the above structure does not constitute a limitation of the above display device provided in the embodiments of the present disclosure; in other words, more or fewer components as described above may be included in the above display device provided in the embodiments of the present disclosure, or combinations of some of the components, or different arrangements of the components.

In summary, the array substrate, the display panel, and the display device are provided in the embodiments of the present disclosure, the second electrode includes the first sub-connection portion and the second sub-connection portion disposed on opposite sides of the first sub-connection portion and connected to the first sub-connection portion, the orthographic projection of the first sub-connection portion on the base substrate falls into the orthographic projection of the first opening area of the first electrode on the base substrate, and the orthographic projection of the second sub-connection portion disposed on opposite sides of the first sub-connection portion on the base substrate overlaps with the orthographic projection of the first electrode on the base substrate and the orthographic projection of the first opening area on the base substrate. When there is an offset of all the second electrodes included in the array substrate due to a process deviation, i.e., the second sub-connection portions located on opposite two sides of the first sub-connection portion are offset, compared to the case in which there is no offset, opposite two sides of the first sub-connection portion are connected to the second sub-electrode. In each second electrode, an overlapping area of the orthographic projection of the second sub-connection portion located on one side of the first sub-connection portion on the base substrate and the orthographic projection of the first electrode on the base substrate increases, and an overlapping area of the orthographic projection of the second sub-connection portion located on the other side of the first sub-connection portion on the base substrate and the orthographic projection of the first electrode on the base substrate decreases. Since the second sub-connection portion disposed on the opposite two sides of the first sub-connection portion has the same offset, the change of the overlapping area of the orthographic projection of the second sub-connection portions disposed on the opposite two sides of the first sub-connection portion and the orthographic projection of the first electrode on the base substrate can complement. Even if the position of the second electrode is offset due to process deviations, the parasitic capacitance between each second electrode and the first electrode is still equal, avoiding significant differences in the charging rate of different second electrodes caused by different parasitic capacitances between the second electrode and the first electrode. When the array substrate is applied to a display product, differences in the brightness of different sub-pixel areas can thus be avoided. When the user moves to view, it can avoid aggravation of the brightness difference, avoid the appearance of a head-shaking pattern, improve the display effect, and enhance the user experience.

Although preferred embodiments of the present disclosure have been described, those skilled in the art may make additional changes and modifications to these embodiments once the underlying inventive concepts are known. Therefore, the appended claims are intended to be construed to include the preferred embodiments as well as all changes and modifications that fall within the scope of the present disclosure.

Obviously, those skilled in the art can make various changes and variations to the present disclosure without departing from the spirit and scope of the present disclosure. Thus, to the extent that such modifications and variations of the present disclosure fall within the scope of the claims of the present disclosure and their technical equivalents, the present disclosure is intended to encompass such modifications and variations.

1.-32. (canceled)

33. An array substrate, comprising:
a first base substrate, comprising a plurality of sub-pixel areas arrayed along a first direction and a second direction and a wiring area between adjacent sub-pixel areas; wherein the first direction intersects with the second direction;
a plurality of thin-film transistors, disposed on one side of the first base substrate in the wiring area; wherein each of the plurality of thin-film transistors comprises a first pole, a second pole and a third pole;
a first electrode, disposed on one side of the first pole back from the first base substrate, wherein the first electrode comprises a plurality of first opening areas; wherein an orthographic projection of the first opening areas on the first base substrate falls within the wiring area, and the orthographic projection of the first opening areas on the first base substrate overlaps with an orthographic projection of the first pole on the first base substrate;
a plurality of second electrodes, disposed on the same side of the first base substrate as the first electrode; wherein each of the plurality of second electrodes comprises a first connection portion; the first connection portion comprises a first sub-connection portion electrically connected to the first pole and a second sub-connection portion electrically connected to the first sub-connection portion; the second sub-connection portion comprises structures respectively located on opposite sides of the first connection portion; an orthographic projection of the first sub-connection portion on the first base substrate falls within the orthographic projection of the first opening areas on the first base substrate, and an orthographic projection of the second sub-connection portion on the first base substrate overlaps with the orthographic projection of the first pole on the first base substrate and the orthographic projection of the first opening areas on the first base substrate.

34. The array substrate according to claim 33, wherein the second sub-connection portion comprises a first structure and a second structure;
in the first direction, the first structure and the second structure are disposed on both sides of the first sub-connection portion respectively;
wherein the first structure comprises a first region adjacent to the first sub-connection portion, and the second structure comprises a second region adjacent to the first sub-connection portion;
in the first direction, a spacing between the orthographic projection of the first sub-connection portion on the first base substrate and an orthographic projection of an edge of the first opening area on a side of the first sub-connection portion toward the first structure on the first base substrate is less than a width of an orthographic projection of the first region on the first base substrate, and a spacing between the orthographic projection of the first sub-connection portion on the first base substrate and an orthographic projection of an edge of the first opening area on a side of the first sub-connection portion toward the second structure on the first base substrate is less than a width of an orthographic projection of the second region on the first base substrate.

35. The array substrate according to claim 34, wherein the first structure comprises at least one first sub-structure connected to the first sub-connection portion; the second structure comprises at least one second sub-structure connected to the first sub-connection portion;
in the second direction, a maximum width of the orthographic projection of the first sub-connection portion on the first base substrate is less than a width of the orthographic projection of the first opening areas on the first base substrate, the maximum width of the orthographic projection of the first sub-connection portion on the first base substrate is greater than a total width of an orthographic projection of the first sub-structure in the first region on the first base substrate, the maximum width of the orthographic projection of the first sub-connection portion on the first base substrate is greater than a total width of an orthographic projection of the second sub-structure in the second region on the first base substrate.

36. The array substrate according to claim 35, wherein, in the second direction, the total width of the orthographic projection of the first sub-structure in the first region on the first base substrate is equal to the total width of the orthographic projection of the second sub-structure in the second region on the first base substrate.

37. The array substrate according to claim 34, wherein the plurality of sub-pixel areas and a plurality of wiring areas are divided into a plurality of sub-pixel columns arranged along the first direction and extending along the second direction; the plurality of second electrodes comprise a plurality of first sub-electrodes and a plurality of second sub-electrodes;
the first sub-electrodes and the thin-film transistors electrically connected to the first sub-electrodes are located in the same sub-pixel column;
the second sub-electrodes and the thin-film transistors electrically connected to the second sub-electrodes are located in different sub-pixel columns.

38. The array substrate according to claim 34, wherein the second electrode further comprises: a pixel portion corresponding to the sub-pixel area and connected to the first connection portion;
the second sub-connection portion of a first sub-electrode further comprises: a third structure; in the second direction, the third structure is between the first structure and the pixel portion; the third structure is electrically connected to the pixel portion, and at least one of the first sub-connection portion and the first structure is connected to the third structure.

39. The array substrate according to claim 38, wherein in the first sub-electrode, an orthographic projection of the third structure on the first base substrate does not overlap with the first opening area;
wherein in the first sub-electrode and the thin-film transistor corresponding to the first sub-electrode, in the first direction, the first structure and the second pole are located on the same side of the first opening area; an orthographic projection of the first structure on the first base substrate overlaps with an orthographic projection of the second pole on the first base substrate.

40. The array substrate according to claim 39, wherein in the first sub-electrode, in the first direction, a length of the orthographic projection of the first structure on the first base substrate is greater than a length of an orthographic projection of the second structure on the first base substrate.

41. The array substrate according to claim 38, wherein an orthographic projection of the third structure on the first base substrate overlaps with the first opening area;
wherein in the first sub-electrode, the second sub-connection portion further comprises a fourth structure; in the second direction, the third structure and the fourth structure are disposed on both sides of the first sub-connection portion respectively.

42. The array substrate according to claim 41, wherein in the first sub-electrode, the third structure comprises a third region adjacent to the first sub-connection portion, and the fourth structure comprises a fourth region adjacent to the first sub-connection portion;
in the second direction, a spacing between the orthographic projection of the first sub-connection portion on the first base substrate and an orthographic projection of an edge of the first opening area on a side of the first sub-connection portion toward the third structure on the first base substrate is less than a width of an orthographic projection of the third region on the first base substrate, and a spacing between the orthographic projection of the first sub-connection portion on the first base substrate and an orthographic projection of an edge of the first opening area on a side of the first sub-connection portion toward the fourth structure on the first base substrate is less than a width of an orthographic projection of the fourth region on the first base substrate;
wherein the third structure comprises at least one third sub-structure connected to the first sub-connection portion, and the fourth structure comprises at least one fourth sub-structure connected to the first sub-connection portion;
in the first direction, a total width of an orthographic projection of the third sub-structure in the third region on the first base substrate is equal to a total width of an orthographic projection of the fourth sub-structure in the fourth region on the first base substrate.

43. The array substrate according to claim 38, wherein the second sub-connection portion of the second sub-electrode further comprises: a fifth structure, the fifth structure is connected to the first structure and the pixel portion in the second direction between the first structure and the pixel portion.

44. The array substrate according to claim 38, wherein an orthographic projection of the pixel portion of the first sub-electrode on the first base substrate has a first overlapping area with an orthographic projection of the first electrode on the first base substrate, an orthographic projection of the pixel portion of the second sub-electrode on the first base substrate has a second overlapping area with the orthographic projection of the first electrode on the first base substrate; an orthographic projection of the first connection portion of the first sub-electrode on the first base substrate has a third overlapping area with the orthographic projection of the first electrode on the first base substrate, an orthographic projection of the first connection portion of the second sub-electrode on the first base substrate has a fourth overlapping area with the orthographic projection of the first electrode on the first base substrate; the first overlapping area is approximately equal to the second overlapping area, and the third overlapping area is approximately equal to the fourth overlapping area.

45. The array substrate according to claim 37, wherein the first electrode further comprises a plurality of second opening areas disposed in the wiring area; an orthographic projection of the second opening areas on the first base substrate overlaps with an orthographic projection of the first connection portion of the second sub-electrode on the first base substrate.

46. The array substrate according to claim 37, wherein the first sub-electrode is arranged alternately with the second sub-electrode in the first direction and the first sub-electrode is arranged alternately with the second sub-electrode in the second direction;
wherein the array substrate further comprises:
a plurality of data lines, disposed on one side of the first electrode toward the first base substrate, and arranged in the first direction and extending in the second direction; wherein each of the plurality of data lines is electrically connected to the second pole of the thin-film transistor; and two sub-pixel columns are provided between two adjacent data lines;
the plurality of wiring areas, divided into a plurality of wiring area rows extending in the first direction; wherein the wiring area rows comprise a plurality of first sub-areas and a plurality of second sub-areas; each of the plurality of first sub-areas is adjacent to the sub-pixel areas in the second direction, and the first sub-area is located between two adjacent data lines; each of the plurality of second sub-areas is adjacent to the sub-pixel areas in the second direction, and the second sub-area is located between two adjacent data lines; the first sub-areas are arranged alternately with the second sub-areas in the second direction;
the plurality of thin-film transistors, comprising a plurality of first thin-film transistors and a plurality of second thin-film transistors; wherein the first thin-film transistor is electrically connected to the first sub-electrode, and the second thin-film transistor is electrically connected to the second sub-electrode; the first thin-film transistor is disposed in the first sub-area, and the second thin-film transistor is disposed in the second sub-area;
wherein in an M^{th} wiring area row, an m number of second sub-areas are provided between two first sub-areas; in an (M+1)^{th} wiring area row, an m number of first sub-areas are provided between two second sub-areas; wherein M is an integer greater than or equal to 1, m is an integer greater than 1, and (M+1) is less than or equal to a total number of the wiring area rows.

47. The array substrate according to claim 46, wherein the array substrate further comprises:
a plurality of scan lines, located on one side of the first electrode toward the first base substrate in the wiring area; wherein the plurality of scan lines extend in the first direction and are arranged along the second direction; the plurality of scan lines comprise a plurality of first scan lines and a plurality of second scan lines; the first scan lines are arranged alternately with the second scan lines; and one first scan line and one second scan line are provided between two adjacent sub-pixel areas in the second direction; the scan lines are disposed in the same layer with and electrically connected to the third pole of the thin-film transistor; the scan lines comprise a first compensation portion corresponding to the thin-film transistor;
the first pole of the thin-film transistor, comprising a first portion, and a second portion and a third portion disposed in the first direction on both sides of the first portion respectively;
wherein an orthographic projection of the first portion on the first base substrate falls within an orthographic projection of an area between the third pole and the first compensation portion on the first base substrate, an orthographic projection of the second portion on the first base substrate overlaps with an orthographic projection of the third pole on the first base substrate, and an orthographic projection of the third portion on the first base substrate overlaps with an orthographic projection of the first compensation portion on the first base substrate.

48. The array substrate according to claim 47, wherein in the second direction, a width of the orthographic projection of the third portion on the first base substrate is equal to a width of an orthographic projection of one side of the second portion proximate to the first portion on the first base substrate.

49. The array substrate according to claim 47, wherein in the first sub-area, the scan line comprises: a first portion extending in the first direction, and a second portion extending in a third direction and connected to the first portion; the third direction intersects with both the first direction and the second direction; and the first compensation portion is disposed on one side of the second portion toward the third pole;
wherein in the second sub-area, the scan line comprises: a second portion extending in the first direction, and a third portion extending in a third direction and connected to the second portion; the third direction intersects with both the first direction and the second direction; the first compensation portion is disposed on one side of the third portion toward the third pole.

50. The array substrate according to claim 47, wherein in the second sub-area, the scan line comprises: a second portion extending in the first direction; the first compensation portion is connected to the second portion in the second direction, and the first compensation portion and the third pole are located on the same side of the second portion in the second direction;
wherein in the second sub-area, an orthographic projection of the second opening area on the first base substrate does not overlap the scan lines, and the orthographic projection of the second opening area on the first base substrate falls within an orthographic projection of a region between two adjacent first compensation portions on the first base substrate;
wherein in at least a part of the second sub-area, the second opening areas corresponding to the first connection portions of two second sub-electrodes are integrally connected.

51. The array substrate according to claim 38, wherein the array substrate comprises a plurality of scan lines;
an orthographic projection of the pixel portion on the first base substrate overlaps with an orthographic projection of the scan lines on the first base substrate;
wherein the first electrode comprises a plurality of slit units, or the pixel portion comprises a slit unit; an orthographic projection of the slit unit on the first base substrate overlaps with the sub-pixel area;
the slit unit comprises a first sub-unit and a second sub-unit arranged alternately in the second direction; the first sub-unit comprises a plurality of first slits extending in a fourth direction and arranged along the first direction, and the second sub-unit comprises a plurality of second slits extending in a fifth direction and arranged along the first direction; the fourth direction intersects with the fifth direction, and the fourth direction intersects with both the first direction and the second direction; the fifth direction intersects with both the first direction and the second direction;
the array substrate further comprises a plurality of first electrode wires located on one side of the first electrode towards the first base substrate and extending along the first direction and arranged along the second direction; the first electrode wires are electrically connected to the first electrode;
an orthographic projection of the first electrode wires on the first base substrate overlaps with an orthographic projection of a connection location of the first sub-unit and the second sub-unit on the first base substrate.

52. A display panel, comprising:
an array substrate; wherein the array substrate comprises a plurality of data lines;
an opposite substrate, disposed opposite the array substrate, comprising a second base substrate, and a plurality of spacers disposed on one side of the second base substrate toward a liquid crystal layer; an orthographic projection of the spacers on the first base substrate falls within the wiring area, and the orthographic projection of the spacers on the first base substrate overlaps with an orthographic projection of the data lines on the first base substrate;
the liquid crystal layer, between the array substrate and the opposite substrate;
wherein the array substrate further comprises:
a first base substrate, comprising a plurality of sub-pixel areas arrayed along a first direction and a second direction and a wiring area between adjacent sub-pixel areas; wherein the first direction intersects with the second direction;
a plurality of thin-film transistors, disposed on one side of the first base substrate in the wiring area; wherein each of the plurality of thin-film transistors comprises a first pole, a second pole and a third pole;
a first electrode, disposed on one side of the first pole back from the first base substrate, and comprising a plurality of first opening areas; wherein an orthographic projection of the first opening areas on the first base substrate falls within the wiring area, and the orthographic projection of the first opening areas on the first base substrate overlaps with an orthographic projection of the first pole on the first base substrate;
a plurality of second electrodes, disposed on the same side of the first base substrate as the first electrode; wherein each of the plurality of second electrodes comprises a first connection portion; the first connection portion comprises a first sub-connection portion electrically connected to the first pole and a second sub-connection portion electrically connected to the first sub-connection portion; the second sub-connection portion comprises structures respectively located on opposite sides of the first connection portion; an orthographic projection of the first sub-connection portion on the first base substrate falls within the orthographic projection of the first opening areas on the first base substrate, and an orthographic projection of the second sub-connection portion on the first base substrate overlaps with the orthographic projection of the first pole on the first base substrate and the orthographic projection of the first opening areas on the first base substrate.
